(19) United States
(12) Patent Application Publication
(10) Pub. No.: US 2025/0151229 A1
(43) Pub. Date: May 8, 2025

(54) FLUID CHANNEL MODULE AND POWER DEVICE INCLUDING SAME

(71) Applicant: LS ELECTRIC CO., LTD., Anyang-si, Gyeonggi-do (KR)

(72) Inventor: Kyu Hwa KIM, Anyang-si, Gyeonggi-do (KR)

(21) Appl. No.: 18/835,897

(22) PCT Filed: Jan. 20, 2023
(86) PCT No.: PCT/KR2023/001058

§ 371 Date: Aug. 5, 2024

(30) Foreign Application Priority Data
Mar. 8, 2022 (KR) 10-2022-0029273

(51) Int. Cl. H05K 7/20

(52) U.S. Cl. CPC H05K 7/20272; H05K 7/20927

(57) ABSTRACT

Disclosed are a fluid channel module and a power device including same. A fluid channel module according to an aspect of the present disclosure may include: a fluid channel division member communicating with a space of a housing to allow a fluid flowing in the space to be introduced thereinto; a duct member which is coupled to the fluid channel division member and communicates with the fluid channel division member to allow the fluid to flow therethrough; and a vortex formation member which is coupled to the duct member and communicates with the duct member to allow the fluid to flow therethrough, wherein the vortex formation member includes a vortex protrusion formed on the inner surface of the end in the extension direction thereof and configured such that the fluid is discharged while forming a vortex.

### CROSS-REFERENCE TO RELATED APPLICATIONS

This application is the National Stage filing under 35 U.S.C. 371 of International Application No. PCT/KR2023/001058, filed on Jan. 20, 2023, which claims the benefit of earlier filing date and right of priority to Korean Application No. 10-2022-0029273, filed on Mar. 8, 2022, the contents of which are all hereby incorporated by reference herein in their entirety.

### FIELD

The present disclosure relates to a fluid channel module and a power device including same, and more particularly, to a fluid channel module having a structure capable of forming a fluid channel of a fluid for cooling to improve cooling efficiency and a power device including same.

### BACKGROUND

The power device refers to an arbitrary device that is electrically connected to an external power source or load and can receive or transmit power. The power device includes inverters, capacitors, and PCBs for controlling them, so that the transmitted power can be processed and delivered according to the load.

As the power device operates, heat is generated in various components provided in the power device. When each component is overheated, there is a possibility of damage caused by heat. In this case, there is a risk that the operation reliability of each component and the power device may deteriorate. Furthermore, when overheating continues, there is also a risk of safety accidents such as fire.

Therefore, a heat dissipation member is provided in the power device currently in use. The heat dissipation member may be particularly located adjacent to a device that generates a lot of heat, and may be configured to receive and dissipate the generated heat. For example, a fin-type heat dissipation member may be provided that receives heat in the form of conduction and emits heat in the form of convection.

However, in the case of a conventional type of power device, only the components that the heat dissipation member can be contacted and coupled can be configured to be cooled. That is, in the case of a member such as a PCB to which the heat dissipation member may not be in direct contact or coupled, it is difficult to easily perform cooling.

In addition, as the power device is advanced and integrated, the number of cases where a plurality of PCBs are provided is increasing. In this case, heat may also be generated in a space formed between the plurality of PCBs. However, the space is too narrow to accommodate the heat dissipation member, so effective cooling is difficult.

Korean Patent Registration No. 10-09982313 discloses a PCB cooling device. More specifically, disclosed is a PCB cooling device capable of dissipating heat from a PCB by directly contacting and releasing a heat dissipation member made of a shape memory alloy with semiconductor elements in contact with the PCB.

However, since the PCB cooling device disclosed in the prior document is provided in a plate shape similar to that of a PCB, it is difficult to contribute to the miniaturization of a device provided with the PCB and the PCB cooling device. Furthermore, the PCB cooling device disclosed in the prior document is made of a material using a shape memory alloy, and thus there is a risk that the manufacturing cost will increase, and the manufacturing process will become complicated.

Korean Patent Laid-open Publication No. 10-2021-0002271 discloses a PCB cooling device. Specifically, disclosed is a PCB cooling device capable of cooling a PCB by spraying cooling water onto the PCB.

However, the PCB cooling device disclosed in the prior document is a water cooling type rather than an air cooling type. Therefore, in order for the prior document to be applied, a separate process for waterproofing the PCB is required.

Furthermore, the PCB cooling device disclosed in the prior document requires a separate cooling water tank and a pipe member for supplying and circulating cooling water. Therefore, the prior document is difficult to achieve simplified and miniaturization of the structure of the power device.
Korean Patent Registration No. 10-0998213 (2010 Dec. 3.)
Korean Patent Laid-Open Publication No. 10-2021-0002271 (2021 Jan. 7.)

### SUMMARY

The present disclosure is to solve the above problems, and it is an object of the present disclosure to provide a fluid channel module having a structure in which components may be effectively cooled and a power device including same.

Another object of the present disclosure is to provide a fluid channel module having a structure in which a blind spot where a fluid for cooling cannot flow may be minimized and a power device including the same.

Still another object of the present disclosure is to provide a fluid channel module having a structure in which a fluid for cooling may flow smoothly and a power device including same.

Still another object of the present disclosure is to provide a fluid channel module having a structure in which components may be effectively cooled without a separate fluid supply source and a power device including same.

Still another object of the present disclosure is to provide a fluid channel module having a structure in which the degree of freedom in design and degree of freedom in arrangement may be improved and a power device including same.

The technical problems of the present disclosure are not limited to the above-mentioned technical problems, and other technical problems not mentioned may be clearly understood by those skilled in the art to which the present disclosure pertains from the following description.

According to an aspect of the present disclosure, there is provided a fluid channel module including a fluid channel division member communicating with a space of a housing to allow a fluid flowing in the space to be introduced thereinto; a duct member which is coupled to the fluid channel division member and communicates with the fluid channel division member to allow the fluid to flow therethrough; and a vortex formation member which is coupled to the duct member and communicates with the duct member to allow the fluid to flow therethrough, wherein the vortex formation member includes a vortex protrusion formed on an inner surface of an end in an extension direction thereof and configured such that the fluid is discharged while forming a vortex.

In this case, there may be provided a fluid channel module, wherein the vortex formation member may include a vortex body formed to extend in one direction and having one end in the extending direction coupled to the duct member; and a vortex arm formed to extend in the other direction, and having one end in the extending direction coupled to the vortex formation member and having the other end in the extending direction formed open to discharge the fluid.

In addition, there may be provided a fluid channel module, wherein the vortex formation member includes a first vortex hollow formed through the inside of the vortex body along the one direction and communicating with the inside of the duct member; and a second vortex hollow formed through the inside of the vortex arm along the other direction and communicating with the first vortex hollow and the outside, respectively.

In this case, there may be provided a fluid channel module, wherein the fluid is branched into one portion flowing in the first vortex hollow along the one direction; and another portion passing through the second vortex hollow from the first vortex hollow to be exposed to the outside.

In addition, there may be provided a fluid channel module, wherein the vortex arm are formed in plural, and the plurality of vortex arms are coupled to an outer circumference of the vortex body at different positions.

In addition, there may be provided a fluid channel module, wherein the vortex protrusion is formed to protrude from the inner surface of the other end of the vortex arm toward the radially inside.

In this case, there may be provided a fluid channel module, wherein the vortex protrusion is provided in plural, and the plurality of vortex protrusions are disposed to be spaced apart from each other along an inner circumferential surface of the vortex arm.

In addition, there may be provided a fluid channel module, wherein the vortex formation member is formed to extend along one direction, and the duct member is formed to extend obliquely at a predetermined angle with respect to the one direction.

In this case, there may be provided a fluid channel module, wherein one end of the duct member in an extending direction is coupled to the vortex formation member, and the other end of the duct member in the extending direction is coupled to the fluid channel division member.

In addition, there may be provided a fluid channel module, wherein the duct member is made of a flexible material.

In this case, there may be provided a fluid channel module, wherein the fluid channel division member includes a dividing body coupled to the duct member; and a divided space formed inside the dividing body and open to allow the fluid to flow therein.

In addition, there may be provided a fluid channel module, wherein the dividing body includes a first dividing surface surrounding one portion of the divided space; a second dividing surface extending at a predetermined angle with respect to the first dividing surface and surrounding another portion of the divided space; and a third dividing surface and a fourth dividing surface each continuous with the first dividing surface and the second dividing surface, and disposed to face each other with the divided space interposed therebetween, wherein the duct member extends to be inclined by the predetermined angle at which the second dividing surface extends.

In this case, there may be provided a fluid channel module, wherein the fluid channel division member and the duct member are disposed to face each other with a support plate, which is disposed in the space of the housing, interposed therebetween, and are coupled to one side and the other side of the support plate, respectively, and a support through-hole formed through the inside of the support plate to communicate with the fluid channel division member and the duct member, respectively.

In addition, according to an aspect of the present disclosure, there is provided a power device including a housing in which a housing space communicating with the outside is formed; an electrical connection unit accommodated in the housing space, and electrically connected to the outside; and a fluid channel module coupled to the electrical connection unit, and configured to form a fluid channel of a fluid for cooling the electrical connection unit, wherein the electrical connection unit comprises a plurality of substrates disposed to be spaced apart from each other and to be stacked, wherein the fluid channel module includes a fluid channel division member communicating with a housing space to allow a fluid flowing in the housing space to be introduced thereinto; a duct member which is coupled to one of the plurality of the substrates and the fluid channel division member, and communicates with the fluid channel division member to allow the fluid flow therethrough; and a vortex formation member which is coupled to the one of the substrates and another one adjacent to the one of the substrates, and communicates with the duct member to allow the fluid flow therethrough, and wherein the vortex formation member includes a vortex protrusion formed on an inner surface of an end in an extension direction thereof and configured such that the fluid is discharged while forming a vortex.

In this case, there may be provided a power device, wherein the vortex formation member includes a first vortex formation member coupled to one pair of substrates adjacent to each other among the plurality of the substrates; and a second vortex formation member coupled to the other pair of substrates adjacent to each other among the plurality of the substrates, and communicating with the first vortex formation member, wherein the plurality of the substrates includes a first substrate positioned at a lowermost side, wherein a lower side thereof is coupled to the duct member and an upper side thereof is coupled to the first vortex formation member; a second substrate disposed on an upper side of the first substrate to be spaced apart from the first substrate, wherein a lower side thereof is coupled to the first vortex formation member, and an upper side thereof is coupled to the second vortex formation member; and a third substrate disposed on an upper side of the second substrate to be spaced apart from the second substrate, wherein a lower side thereof is coupled to the second vortex formation member.

In addition, there may be provided a power device, wherein a first substrate through-hole, a second substrate through-hole, and a third substrate through-hole are formed through the inside of the first substrate, the second substrate, and the third substrate, respectively, the duct member communicates with the first substrate through-hole, the first vortex formation member communicates with the first substrate through-hole and the second substrate through-hole, and the second vortex formation member communicates with the second substrate through-hole.

In this case, there may be provided a power device, wherein the fluid introduced into the first vortex formation member is partially discharged to a first flow space, which is a space formed between the first substrate and the second substrate, and the remaining partially flows to the second vortex formation member, and wherein the fluid introduced into the second vortex formation member is partially discharged to a second flow space, which is a space formed between the second substrate and the third substrate, and the remaining is partially discharged to a third flow space, which is a space formed on an upper side of the third substrate.

In addition, there may be provided a power device, wherein the vortex formation member includes a vortex body extending in a direction in which the plurality of substrates are stacked, and having a first vortex hollow formed through therein along the extension direction; and a vortex arm formed to extend in a direction different from the vortex body, and having a second vortex hollow formed through therein along the extension direction, the second vortex hollow communicating with the first vortex hollow and the flow space, respectively.

In this case, there may be provided a power device, wherein the vortex protrusion is located adjacent to an end of an inner surface of the vortex arm surrounding the second vortex hollow.

In addition, there may be provided a power device, wherein the housing includes a blower coupled to one surface thereof to provide a transfer force for flowing an external fluid to the housing space, and wherein the fluid channel division member is disposed on a fluid channel through which a fluid introduced into the housing space flows by a transfer force and allows a portion of the introduced fluid to flow into the fluid channel division member.

According to the above configuration, the components of the fluid channel module and the power device including same according to the embodiment of the present disclosure may be effectively cooled.

The components accommodated inside the housing may be cooled by external fluid introduced into the housing space. The external fluid flows in the housing space and exchanges heat with the accommodated components to cool the components.

The fluid channel module is provided with the fluid channel division member communicating with the housing space. The fluid introduced into the housing space may be divided, and a portion thereof may flow in the fluid channel division member.

The fluid channel division member includes a dividing surface formed to extend obliquely. The fluid introduced into the fluid channel division member may flow along the dividing surface and may flow toward the duct member and the vortex formation member. The duct member and the vortex formation member communicate with the fluid channel division member, respectively.

The vortex formation member includes a vortex protrusion formed in a portion in which the inside and the outside communicate with each other. The fluid introduced into the vortex formation member is discharged to the outside, and is formed as a vortex by the vortex protrusion. In other words, the fluid discharged from the vortex formation member may flow in various forms and heat exchange with components may proceed smoothly.

Accordingly, each component of the power device may be effectively cooled by the fluid discharged from the vortex formation member.

In addition, according to the configuration, the fluid channel module and the power device including the same according to an embodiment of the present disclosure may minimize a blind spot where fluid for cooling cannot flow.

A plurality of substrates are spaced apart from each other and stacked. A flow space is formed between the plurality of substrates. The vortex formation member may be disposed in the flow space, and the fluid introduced into the vortex formation member may be discharged into the flow space. The fluid discharged into the flow space may flow while cooling the substrate and the components coupled to the substrate.

Therefore, when compared to the case where the fluid channel module is not provided, the fluid for cooling may flow in a wide space and various spaces. Accordingly, the blind spot where fluid for cooling cannot flow may be minimized.

As a result, the components disposed to be spaced apart from the heat dissipation member, such as the substrate, may also be effectively cooled.

In addition, according to the above configuration, the fluid channel module and the power device including the same according to the embodiment of the present disclosure may allow the fluid for cooling to flow smoothly.

The fluid channel division member includes a divided space in which the divided fluid flows and a dividing surface that partially surrounds the divided space and guides the divided fluid toward the duct member. The divided fluid may flow along the dividing surface and may flow toward the duct member.

In an embodiment, the inner surface of the duct member may extend obliquely. In the above embodiment, the slope of the inner surface of the duct member may be formed to correspond to the slope of the divided surface. Furthermore, the inner surface of the duct member may extend smoothly without a separate protrusion.

Therefore, the fluid flowing in the housing space may be discharged to the flow space via the fluid channel division member, the duct member, and the vortex formation member without significant flow resistance. Accordingly, the fluid for cooling may flow smoothly.

In addition, according to the above configuration, the fluid channel module and the power device including the same according to an embodiment of the present disclosure may effectively cool components without a separate fluid supply source.

The fluid for cooling the components of the power device may be applied to a transfer force by the operation of the blower. When the blower is operated, the fluid staying in the outside of the housing may be introduced into the housing space. The fluid may continuously flow in the housing space using the transfer force applied by the blower. That is, a separate member for supplying the fluid for cooling is not required.

Meanwhile, the fluid channel division member is disposed on the path of the fluid flowing in the housing space. That is, a separate device for guiding the fluid toward the fluid channel division member is not required. When the blower is operated, a portion of the fluid introduced into the housing space may be introduced into the fluid channel division member, and the fluid may flow to cool the substrate.

Therefore, the fluid may flow without a separate supply source and an additional power source to cool the various components.

In addition, according to the above configuration, the fluid channel module and the power device including the same according to the embodiment of the present disclosure may improve the degree of freedom in design and degree of freedom in arrangement.

The fluid channel module is positioned between the substrates and is configured to discharge the fluid to the space between the substrates. The fluid channel module may be manufactured in a small size according to the size of a small space formed between the substrates. That is, even if the fluid channel module is provided, the size of the power device is not increased.

The vortex formation member of the fluid channel module may be provided in plural. The plurality of vortex formation members may be positioned between each pair of substrates disposed adjacent to each other. When the number of substrates increases, the vortex formation member may also be additionally provided to correspond thereto. That is, the number of vortex formation members may be adjusted so that scale-up or scale-down of the fluid channel module may be easily performed.

In addition, the fluid channel module is positioned in the dead space formed between the substrates. That is, no additional space is required to provide the fluid channel module.

Therefore, the utilization of the inner space of the power device is improved, and various forms of the inner space may be modified according to the capacity of the power device. Therefore, the degree of freedom in design and degree of freedom in arrangement may be improved.

The effect of the present disclosure is not limited to the above effects, and it should be understood to include all effects that can be inferred from the detailed description of the present disclosure or the claims of the disclosure.

### BRIEF DESCRIPTION OF THE DRAWINGS

FIG. 1 is a perspective view illustrating a power device according to an embodiment of the present disclosure.

FIG. 2 is a partially open perspective view illustrating an internal configuration of the power device of FIG. 1.

FIG. 3 is A-A cross-sectional view illustrating an internal configuration of the power device of FIG. 1.

FIG. 4 is a partially enlarged cross-sectional view illustrating a coupling structure between a fluid channel module and a PCB provided in the power device of FIG. 1.

FIG. 5 is an exploded perspective view illustrating a coupling structure between the fluid channel module and the PCB of FIG. 4.

FIG. 6 is a perspective view illustrating some components of the fluid channel module of FIG. 4.

FIG. 7 is a perspective view illustrating a fluid channel module provided in the power device of FIG. 1.

FIG. 8 is an exploded perspective view illustrating a coupling structure between components of the fluid channel module of FIG. 7.

FIG. 9 is a partially open perspective view illustrating a duct member provided in the fluid channel module of FIG. 7.

FIG. 10 is a side cross-sectional view illustrating a duct member provided in the fluid channel module of FIG. 7.

FIG. 11 is a front cross-sectional view illustrating a vortex formation member provided in the fluid channel module of FIG. 7.

FIG. 12 is a plan cross-sectional view illustrating a vortex formation member provided in the fluid channel module of FIG. 7.

FIG. 13 is a partially perspective view illustrating a modified example of the vortex formation member of FIG. 12.

FIG. 14 is a partially open perspective view illustrating a fluid channel formed inside the fluid channel module of FIG. 7.

FIG. 15 is a side cross-sectional view illustrating a fluid channel formed inside the fluid channel module of FIG. 7.

FIG. 16 is a side cross-sectional view illustrating a fluid channel formed inside the power device of FIG. 1.

FIG. 17 is a forward cross-sectional view illustrating a fluid channel formed inside the power device of FIG. 1.

FIGS. 18 to 21 are partially open perspective views illustrating a fluid channel formed inside the power device of FIG. 1.

### DETAILED DESCRIPTION

Hereinafter, exemplary embodiments of the present disclosure will be described in detail so that those of ordinary skill in the art can readily implement the present disclosure with reference to the accompanying drawings. The present disclosure may be embodied in many different forms and is not limited to the embodiments set forth herein. In the drawings, parts unrelated to the description are omitted for clarity of description of the present disclosure, and throughout the specification, same or similar reference numerals denote same elements.

Terms and words used in the present specification and claims should not be construed as limited to their usual or dictionary definition, and they should be interpreted as a meaning and concept consistent with the technical idea of the present disclosure based on the principle that inventors may appropriately define the terms and concept in order to describe their own disclosure in the best way.

Accordingly, the embodiments described in the present specification and the configurations shown in the drawings correspond to preferred embodiments of the present disclosure, and do not represent all the technical idea of the present disclosure, so the configurations may have various examples of equivalent and modification that can replace them at the time of filing the present disclosure.

In the following description, in order to clarify the features of the present disclosure, descriptions of some components may be omitted.

### 1. Term Definition

The term “communication” used in the following description means that one or more members are connected to each other in fluid communication. In an embodiment, the communication may be formed by a member such as a conduit, a pipe, and channel, etc.

The term “electrically connection” used in the following description means that two or more members are connected to transmit an electrical signal or current. In an embodiment, the electric-current-conducting may be formed in a wired form by a wire member or the like or in a wireless form such as RFID, Bluetooth, Wi-Fi or the like.

The term “fluid” used in the following description means a material in an arbitrary form whose shape or the like may be deformed by an external force. The fluid may be introduced into the interior of the power device 10 and configured to exchange heat with the components of the power device 10. By the heat exchange, various components provided in the power device 10 may be cooled. In an embodiment, the fluid may be a gas such as air.

As used in the following description, the terms “upper side”, “lower side”, “front side”, “rear side”, “left side” and “right side” will be understood with reference to the coordinate system shown throughout the accompanying drawings.

### 2. Description of the Configuration of a Power Device 10 According to an Embodiment of the Present Disclosure

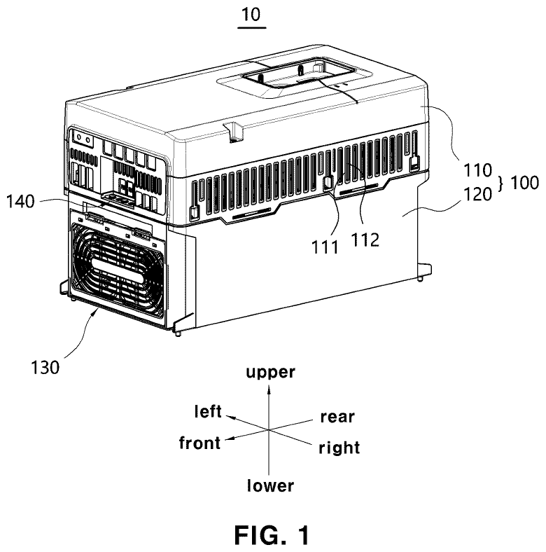

Referring to FIGS. 1 to 5, the power device 10 according to the embodiment of the present disclosure is illustrated.

The power device 10 may be provided in an arbitrary form capable of performing a predetermined function by accommodating various electrical and electronic devices therein. In an embodiment, the power device 10 may be provided as an arbitrary shape device including an inverter, an insulated gate bipolar transistor (IGBT), and a printed circuit board (PCB), etc.

In the above embodiment, the power device 10 may be electrically connected with an external power source or load. In the above embodiment, the power device 10 may be configured to receive power from an external power source, process the received power in various forms, and transmit the power to an external load.

In this case, as the power device 10 is operated, heat may be generated in various components mounted inside the power device 10. When excessive heat is generated, damage to each component of the power device 10 may be caused, resulting in malfunction of the power device 10.

In addition, even when a fluid for cooling each component of the power device 10 is introduced, it is difficult to improve the cooling efficiency when the fluid channel of fluid is not effectively formed. That is, it is preferable that the fluid introduced into the power device 10 flows in various spaces inside the power device 10 and is configured to exchange heat with various components.

Therefore, the power device 10 according to the embodiment of the present disclosure includes the fluid channel module 11 to variously form the fluid channel of the fluid introduced for cooling. Accordingly, the power device 10 according to the embodiment of the present disclosure may effectively cool the components thereof, thereby improving operation reliability.

In the illustrated embodiment, the power device 10 includes a housing 100, an electrical connection unit 200, a fluid channel division member 300, a duct member 400, and a vortex formation member 500. Among the components, the fluid channel module 11 constituting the fluid channel division member 300, the duct member 400, and the vortex formation member 500 will be described separately.

The housing 100 forms the exterior of the power device 10. The housing 100 is a portion where the power device 10 is exposed to the outside. A space may be formed inside the housing 100 to mount various components of the power device 10.

The inside of the housing 100 is electrically connected to an external power source or load. The components accommodated inside the housing 100 may be electrically connected to the external power source or load. For the above electrical connection, a conductive wire member (not shown) may be penetrated inside the housing 100.

The housing 100 may be formed of an electrically insulating material. This is to prevent any electrical connection to an external power source or load, and to prevent accidents such as electric shock with an operator located adjacent to the power device 10.

The housing 100 may be formed of a highly heat-resistant material. It is to prevent safety accidents that may be damaged by heat generated by the components of the power device 10 accommodated in the housing 100 or generated by heat generated by heat. This is to prevent safety accidents that may be caused by damage from heat generated from components of the power device 10 accommodated inside the housing 100 or being heated by the generated heat.

In an embodiment, the housing 100 may be formed of a synthetic resin material such as polycarbonate (PC).

The housing 100 communicates with the outside. The fluid outside the housing 100 may be introduced into the interior of the housing 100. Various components accommodated inside the housing 100 may be cooled while exchanging heat with the introduced fluid.

The housing 100 may be provided in an arbitrary shape capable of mounting the components of the power device 10. In the illustrated embodiment, the housing 100 has a rectangular pillar shape in which an extension length in the front and rear directions is longer than an extension length in the left and right directions and has a height in the vertical direction.

In the illustrated embodiment, the housing 100 includes a first housing 110, a second housing 120, a blower 130, a terminal 140, a housing space 150, and a support plate 160.

The first housing 110 forms a part of the exterior of the housing 100. In the illustrated embodiment, the first housing 110 forms an upper side of the housing 100.

The first housing 110 is coupled to the second housing 120. In an embodiment, the first housing 110 may be removably coupled to the second housing 120. In the above embodiment, the coupling and separation of the first housing 110 and the second housing 120 may be easily performed, thereby simplifying the manufacturing and maintenance of the power device 10.

A space is formed inside the first housing 110. The space communicates with a space formed inside the second housing 120. As will be described later, the space formed inside the first housing 110 may be defined as the first space 151, and the space formed inside the second housing 120 may be defined as the second space 152.

One side of the first housing 110, that is, the lower side in the illustrated embodiment are open. The inside of the first housing 110 may communicate with the inside of the second housing 120 through the one side, that is, the lower side.

The first housing 110 is coupled to the terminal 140. Various components accommodated inside the housing 100 may be electrically connected to the external power source or load through the terminal 140. The terminal 140 is located at one end of the first housing 110 in the longitudinal direction, that is, at the end surface of the front side in the illustrated embodiment.

In the illustrated embodiment, the first housing 110 includes a rib 111 and an air hole 112.

The rib 111 forms a portion of the first housing 110. The rib 111 reinforces the rigidity of the first housing 110. In the illustrated embodiment, the rib 111 is formed in the width direction of the first housing 110, that is, on the left and right sides, respectively.

The rib 111 is formed to extend in the height direction of the first housing 110, that is, in the vertical direction in the illustrated embodiment. Accordingly, the rigidity of the first housing 110 in the height direction may be reinforced.

The rib 111 may be formed in plural. The plurality of ribs 111 may be spaced apart from each other along a longitudinal direction of the first housing 110. In the illustrated embodiment, the ribs 111 are spaced apart from each other along the front and rear directions.

A space in which the plurality of ribs 111 are formed to be spaced apart from each other may be defined as the air hole 112.

The air hole 112 communicates the inner space of the first housing 110, that is, the first space 151, with the outside. A fluid external to the first housing 110, that is, a fluid for cooling, may be introduced into the first space 151 through the air hole 112. In addition, the fluid inside the first housing 110, that is, the fluid that has completed heat exchange, may flow out of the first space 151 through the air hole 112.

The air hole 112 is formed through the surface of the first housing 110. The air hole 112 may be formed at an arbitrary position to communicate the inner space of the first housing 110 with the outside. In the illustrated embodiment, the air hole 112 is formed in the width direction of the first housing 110, that is, on the left and right surfaces, respectively, similar to the rib 111.

The air hole 112 is formed to extend in the height direction of the first housing 110, that is, in the vertical direction in the illustrated embodiment. The shape of the air hole 112 may be changed to correspond to the shape of the rib 111.

The air hole 112 may be formed in plural. The plurality of air holes 112 may be disposed to be spaced apart from each other along the longitudinal direction of the first housing 110. In the illustrated embodiment, the air hole 112 is disposed to be spaced apart from each other along the front and rear directions.

At this time, the air hole 112 is formed between the ribs 111 located adjacent to each other. In other words, the air hole 112 is formed by a pair of ribs 111 located adjacent to each other.

As described above, the rib 111 are formed in plural to be disposed in the longitudinal direction of the first housing 110, that is, in the front and rear directions in the illustrated embodiment. Therefore, the air hole 112 may also be formed in plural to be disposed in the longitudinal direction of the first housing 110, that is, in the front and rear directions in the illustrated embodiment.

Therefore, it will be understood that the ribs 111 and the air holes 112 are alternately disposed continuously along the longitudinal direction of the first housing 110.

The second housing 120 forms another portion of the exterior of the housing 100. In the illustrated embodiment, the second housing 120 forms a lower side of the housing 100.

The second housing 120 is coupled to the first housing 110. In an embodiment, the second housing 120 may be removably coupled to the first housing 110 as described above.

A space is formed inside the second housing 120. The space communicates with a space formed inside the first housing 110. Accordingly, the first space 151 and the second space 152 are communicated as described above.

One side of the second housing 120, that is, an upper side in the illustrated embodiment, are open. The inside of the second housing 120 communicates with the inside of the first housing 110 through the one side, that is, the upper side.

Therefore, each side of the first housing 110 and the second housing 120 facing each other is formed open, and the inside thereof may be said to communicate with each other.

Accordingly, the components of the power device 10 may be accommodated throughout the interior of the first housing 110 and the second housing 120. Additionally, as will be described later, the fluid introduced into one of the first housing 110 and the second housing 120 may flow into the other.

The second housing 120 communicates with the outside. The external fluid may be introduced into the second housing 120 and exchange heat with various components accommodated therein. In the illustrated embodiment, one end of the second housing 120 in the longitudinal direction, that is, the front end, is formed open and communicates with the outside.

The second housing 120 is coupled to the blower 130. Various components accommodated in the housing 100 may be cooled by the fluid introduced by the blower 130.

The blower 130 provides a transfer force for the fluid outside the housing 100 to flow into the housing 100.

The blower 130 may be located at a portion in which the second housing 120 communicates with the outside, and transmit the transfer force in the direction from the outside toward the inside of the second housing 120 to the external fluid. In the illustrated embodiment, the blower 130 is located at one end of the second housing 120 in the longitudinal direction, that is, at the front end. In an embodiment, the blower 130 may be accommodated inside the second housing 120 and may be disposed not to be randomly exposed to the outside.

The blower 130 is electrically connected to the terminal 140. The power necessary for the blower 130 to operate may be transferred from the terminal or external power source that is electrically connected to the terminal 140. In an embodiment, the operator may apply a control signal for controlling the operation of the blower 130 through the terminal 140.

The blower 130 may be provided in an arbitrary form capable of providing transfer power to an external fluid to allow the fluid to flow into the housing 100. In the illustrated embodiment, the blower 130 is provided in the form of a fan including a plurality of blades.

The blower 130 may be provided in plural. The plurality of blowers 130 may be disposed in various forms to apply the transfer force to the external fluid. In the illustrated embodiment, two blowers 130 are provided and disposed side by side in the width direction, that is, the left and right directions, of the housing 100.

The fluid introduced into the inner space of the second housing 120, that is, the second space 152, by the blower 130 may exchange heat with the components accommodated in the second space 152, that is, the switching element 210, the heat dissipation member 220, and the like, to be described later, and may cool them.

In particular, the power device 10 according to an embodiment of the present disclosure may divide the flow of the fluid introduced into the second space 152 and induce the same into the first space 151. Accordingly, the components accommodated in the first space 151, for example, the substrate 230 and the capacitor 250, may be effectively cooled. This will be described later in detail.

The terminal 140 is a portion in which the inner space of the housing 100 is electrically connected to the outside. The terminal 140 electrically connects the external power source or load to various components accommodated in the housing 100.

In an embodiment, the terminal 140 may include a plurality of manipulation members. The manipulation member may be provided with buttons, dials, or touch screens, and may receive various control signals for operating the power device 10.

The terminal 140 is coupled to the first housing 110. The terminal 140 is located at one end of the first housing 110 in the longitudinal direction, that is, at the front end in the illustrated embodiment.

Accordingly, the operator may easily electrically connect the terminal 140 located at the front side to the external power source or load. In addition, in an embodiment in which the manipulation member is provided in the terminal 140, the operator may easily control the power device 10 by manipulating the terminal 140 located in the front side.

The terminal 140 may be disposed at an arbitrary position to electrically connected to various components accommodated in the inner space of the housing 100 and to receive control signals from the operator.

The terminal 140 is electrically connected to other components of the power device 10. In an embodiment, the terminal 140 may be electrically connected to the blower 130 and the electrical connection unit 200.

A space in which various components to be electrically connected to the terminal 140 are mounted, that is, a space formed inside the first housing 110 and the second housing 120, may be defined as the housing space 150.

The housing space 150 is a space formed inside the first housing 110 and the second housing 120. The housing space 150 mounts various components constituting the power device 10. In the illustrated embodiment, the blower 130, the support plate 160, the electrical connection unit 200, and the fluid channel module 11 may be accommodated in the housing space 150.

The housing space 150 is defined surrounded by the first housing 110 and the second housing 120. The housing space 150 is not randomly exposed to the outside by the surfaces of the first housing 110 and the second housing 120.

The housing space 150 communicates with the outside. The external fluid may be introduced into the housing space 150 to cool the accommodated components and then discharged.

The housing space 150 is electrically connected to the outside. Various components accommodated in the housing space 150 may be electrically connected to the external power source or load.

In the illustrated embodiment, the housing space 150 includes a first space 151 and a second space 152.

The first space 151 is a space formed inside the first housing 110. The first space 151 is formed to be surrounded by a surface of the first housing 110. In the illustrated embodiment, a front side, a rear side, an upper side, a left side, and a right side of the first space 151 are surrounded by the surface of the first housing 110.

Therefore, it may be said that the first space 151 is partially surrounded by the surface of the first housing 110.

Another portion of the first space 151, that is, a lower side in the illustrated embodiment, is formed open. The first space 151 communicates with the second space 152 through another portion, that is, the lower side. The external fluid introduced into the second space 152 may flow to the first space 151 by the communication.

The first space 151 communicates with the outside. The fluid flowing from the second space 152 to the first space 151 may be discharged to the outside. The communication may be achieved by the air hole 112 formed in the first housing 110.

At this time, the air hole 112 is not provided with a separate member for limiting the flow direction of the fluid. Therefore, the external fluid may be introduced into the first space 115 through the air hole 112, and may exchange heat with the components accommodated in the first space 115.

Some components of the power device 10 are accommodated in the first space 151. In the illustrated embodiment, some components of the substrate 230 and the fluid channel module 11 are accommodated in the first space 151.

The first space 151 communicates with the second space 152. The components of the power device 10 may be accommodated across the first space 151 and the second space 152.

The second space 152 is a space formed inside the second housing 120. The second space 152 is formed to be surrounded by a surface of the second housing 120. In the illustrated embodiment, a front side, a rear side, a lower side, a left side, and a right side of the second space 152 are surrounded by the surface of the second housing 120.

Therefore, it may be said that the second space 152 is partially surrounded by the surface of the second housing 120.

Another portion of the second space 152, that is, an upper side in the illustrated embodiment, is formed open. The second space 152 communicates with the first space 151 through another portion, that is, the upper side. It is as described above that the external fluid introduced into the second space 152 may flow to the first space 151.

The second space 152 communicates with the outside. Specifically, the second space 152 communicates with the outside through one side of the portion of the second housing 120 where the blower 130 is located, that is, the front side in the illustrated embodiment. The external fluid may be introduced into the second space 152 through the front side by the transfer force applied by the blower 130.

The fluid introduced into the second space 152 may flow while cooling the components accommodated in the second space 152. In addition, some of the fluids introduced into the second space 152 may flow to the first space 151 through the fluid channel module 11.

That is, the fluid channel module 11 communicates with the first space 151 and the second space 152, respectively. Accordingly, the components accommodated in the first space 151 and the components accommodated in the second space 152 may be effectively cooled. This will be described later in detail.

Other components of the power device 10 are accommodated in the second space 152. In the illustrated embodiment, the support plate 160, the switching element 210, the heat dissipation member 220, and the capacitor 250 of electrical connection unit are accommodated in the second space 152.

The support plate 160 supports the fluid channel division member 300 of the fluid channel module 11. The support plate 160 is located in the second space 152.

The support plate 160 physically and partially partitions the first space 151 and the second space 152. The support plate 160 partitions the first space 151 and the second space 152 along the height direction, that is, the vertical direction in the illustrated embodiment.

The support plate 160 is coupled to the heat dissipation member 220 of the electrical connection unit 200. By the coupling, the support plate 160 may be stably maintained in a state of being accommodated in the second space 152. In the illustrated embodiment, the rear end of the support plate 160 is coupled to the heat dissipation member 220.

The support plate 160 is coupled to the fluid channel division member 300. By the coupling, the fluid channel division member 300 may be coupled to the housing 100. Accordingly, it may be said that the support plate 160 supports the fluid channel division member 300.

The support plate 160 may be provided in an arbitrary form capable of partitioning the first space 151 and the second space 152, communicates with the fluid channel division member 300, and supports the fluid channel division member 300. In the illustrated embodiment, the support plate 160 is provided in a rectangular plate shape formed to extend in the longitudinal direction and the width direction of the housing 100, that is, in the front and rear directions and the left and right directions, respectively.

A support through-hole 161 is formed inside the support plate 160. The support through-hole 161 is formed in the thickness direction of the support plate 160, that is, in the vertical direction in the illustrated embodiment.

The support through-hole 161 communicates with the upper side and the lower side of the support plate 160. The communication may allow the first space 151 to communicate with the second space 152.

In addition, the support through-hole 161 may communicate with a divided space 320 of the fluid channel division member 300. Due to the communication, a portion of the fluid introduced into the second space 152 may pass through the divided space 320 and the through-hole (not shown) to flow to the duct member 400.

In an embodiment, the support through-hole 161 may be disposed to overlap some components of the fluid channel module 11, that is, the fluid channel division member 300 and the duct member 400 in the height direction and in the vertical direction thereof in the illustrated embodiment. Therefore, it may be said that the support through-hole 161 forms a fluid channel of the fluid introduced into the second space 152 together with the channel module 11.

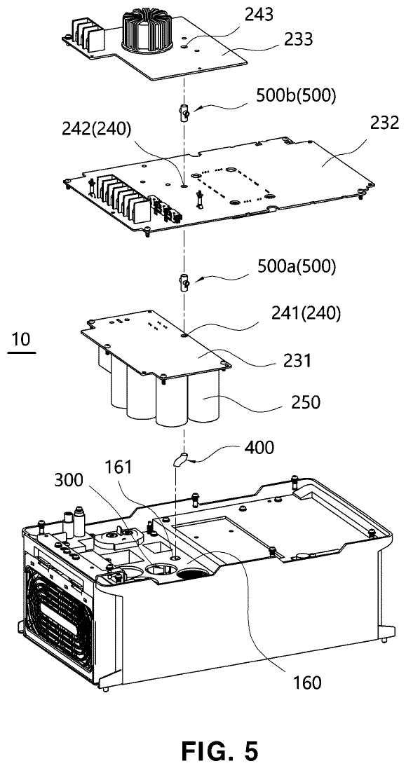

The support through-hole 161 may be an arbitrary shape capable of communicating the fluid channel division member 300 with the duct member 400. In the embodiment shown in FIG. 5, the support through-hole 161 has a circular cross-section and is a cylindrical shape formed to extend in the vertical direction.

Detailed descriptions of the fluid channel of the fluid formed inside the housing 100, including the support through-hole 161 will be given later.

The electrical connection unit 200 is a component that is electrically connected to the external power source or load among the components of the power device 10. The electrical connection unit 200 may be configured in various forms necessary for the power device 10 to perform its function. In the illustrated embodiment, the electrical connection unit 200 is configured to perform a switching function by including the switching element 210. Although not signed a reference numeral, the electrical connection unit 200 may include various types of electronic devices such as an inverter element.

The electrical connection unit 200 is mounted inside the housing 100. The electrical connection unit 200 is not randomly exposed to the outside of the housing 100. In this case, one portion of the components of the electrical connection unit 200 is accommodated inside the first housing 110, and the other portion is accommodated inside the second housing 120.

Specifically, the switching element 210, the heat dissipation member 220, and the capacitor 250 of the electrical connection unit 200 are accommodated in the second space 152. In addition, the substrate 230 of the electrical connection unit 200 is accommodated in the first space 151.

As described above, the first space 151 and the second space 152 communicate with each other. Accordingly, the electrical connection unit 200 may be said to be accommodated across the first space 151 and the second space 152.

The electrical connection unit 200 is electrically connected to the external power source or load. The electrical connection is achieved by electrically connecting the electrical connection unit 200 to the terminal 140. In other words, the electrical connection unit 200 is electrically connected to the external power source or load via the terminal 140.

In the illustrated embodiment, the electrical connection unit 200 includes a switching element 210, a heat dissipation member 220, a substrate 230, a substrate communication hole 240, and a capacitor 250.

The switching element 210 operates switching according to the applied control signal to open and close the circuit. The switching element 210 is electrically connected to the external power source or load through the terminal 140. Since the principle and function of the switching element 210 are well-known in the art, detailed descriptions thereof will be omitted.

The switching element 210 may be provided in an arbitrary form capable of opening and closing the circuit by switching operation. In an embodiment, the switching element 210 may be provided as an Insulated Gate Bipolar Transistor (IGBT).

The switching element 210 is electrically connected to the substrate 230. A control signal for operating the switching element 210 may be transmitted from the substrate 230.

The switching element 210 is electrically connected to the capacitor 250. The power required for the operation of the switching element 210 may be transmitted from the capacitor 250.

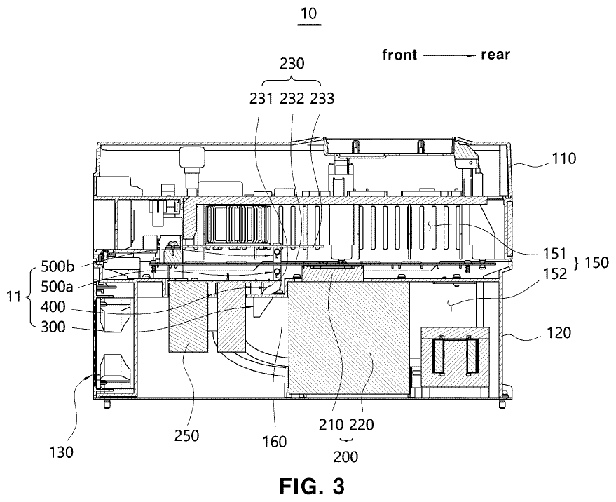

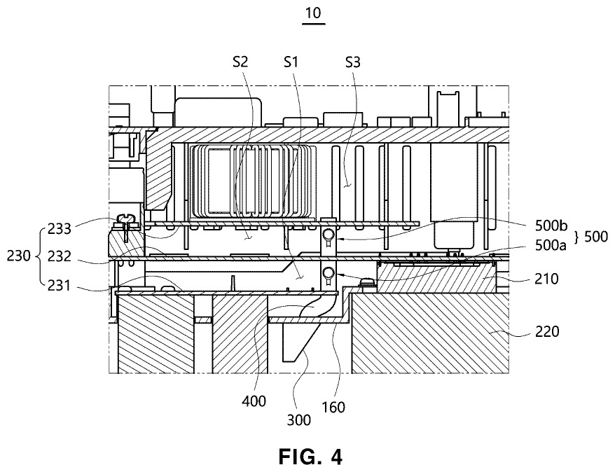

The switching element 210 is accommodated inside the housing 100. Specifically, the switching element 210 is accommodated in the second space 152 and is positioned to be biased to the first space 151. That is, in the embodiment shown in FIGS. 3 to 4, the switching element 210 is positioned to be biased upward in the second space 152.

The switching element 210 is located adjacent to the heat dissipation member 220 and the substrate 230. In the illustrated embodiment, the switching element 210 is located between the heat dissipation member 220 and the second substrate 232.

The switching element 210 may include a plurality of elements. Accordingly, as the switching element 210 is operated, a large amount of heat may be generated. Accordingly, the heat dissipation member 220 is provided to effectively dissipate and cool the switching element 210.

The heat dissipation member 220 receives the heat generated by the switching element 210 and emits the heat to the outside. In this case, the heat emitted by the heat dissipation member 220 may be transferred to the fluid flowing in the second space 152. Accordingly, the switching element 210 may be cooled.

The heat dissipation member 220 is accommodated in the second space 152. The heat dissipation member 220 is located adjacent to the switching element 210. In an embodiment, the heat dissipation member 220 may be in contact with the switching element 210 to receive heat in the form of conduction. In the illustrated embodiment, the heat dissipation member 220 is located on the lower side of the switching element 210, and the upper side thereof is in contact with the lower side surface of the switching element 210.

The heat dissipation member 220 may be provided in an arbitrary form capable of receiving heat from the switching element 210 and transferring the received heat to the fluid introduced into the second space 152 again. In an embodiment, the heat dissipation member 220 may be formed by arranging a plurality of fins spaced apart from each other in parallel.

The heat dissipation member 220 is supported on the second housing 120. In the embodiment shown in FIG. 3, the lower side of the heat dissipation member 220 is supported by the lower inner surface of the second housing 120.

The substrate 230 receives a control signal for the operation of the power device 10. In addition, the substrate 230 controls the switching element 210 and the capacitor 250 according to the applied control signal. The substrate 230 is electrically connected to the terminal 140, the switching element 210, and the capacitor 250, respectively.

The substrate 230 may be provided in an arbitrary form capable of receiving a control signal from the outside and controlling the switching element 210 and the capacitor 250 according to the received control signal. In the illustrated embodiment, the substrate 230 may be provided as a printed circuit board (PCB).

In an embodiment in which the substrate 230 is provided as a PCB, the principle of operation of the PCB is well-known in the art, and thus detailed description will be omitted.

A plurality of substrates 230 may be provided. The plurality of substrates 230 may be disposed to be spaced apart from each other, and may be electrically connected to each other. In addition, the plurality of substrates 230 may be electrically connected to the terminal 140, the switching element 210, and the capacitor 250, respectively.

In the illustrated embodiment, the substrate 230 is provided three including the first substrate 231, the second substrate 232, and the third substrate 233. The first substrate 231, the second substrate 232, and the third substrate 233 are stacked to be spaced apart from each other along the height direction of the housing 100, that is, the vertical direction in the illustrated embodiment.

In the illustrated embodiment, the substrate 230 is disposed to be spaced apart from the heat dissipation member 220. Accordingly, it is difficult to transfer the heat generated by the substrate 230 to the heat dissipation member 220. Similarly, heat generated from an arbitrary electrical element coupled to the substrate 230 is also difficult to be transferred to the heat dissipation member 220.

Accordingly, in the power device 10 according to an embodiment of the present disclosure, the fluid may flow between a plurality of substrates 230 by including the fluid channel module 11. Accordingly, the plurality of substrates 230 and the electrical elements respectively coupled to the plurality of substrates 230 may be effectively cooled. This will be described later in detail.

In the illustrated embodiment, the first substrate 231 is located at the lowermost side. In addition, the third substrate 233 is positioned at the uppermost side, and the second substrate 232 is positioned between the first substrate 231 and the third substrate 233. That is, the first substrate 231, the second substrate 232, and the third substrate 233 are sequentially stacked.

At this time, the first substrate 231, the second substrate 232, and the third substrate 233 are disposed to be spaced apart from each other by a predetermined distance. Therefore, a space by the separation is formed between each of the substrates 231, 232, and 233. In the illustrated embodiment, three substrates 230 are provided, and three spaces may also be formed.

Referring to FIG. 4, a space formed on the upper side of the first substrate 231 may be defined as a first flow space S1. At the same time, the first flow space S1 may also be defined as a space formed under the second substrate 232. Accordingly, the first flow space S1 may be defined as a space formed between the first substrate 231 and the second substrate 232.

In addition, the space formed on the upper side of the second substrate 232 may be defined as the second flow space S2. At the same time, the second flow space S2 may also be defined as a space formed under the third substrate 233. Accordingly, the second flow space S2 may be defined as a space formed between the second substrate 232 and the third substrate 233.

Furthermore, the space formed on the upper side of the third substrate 233 may be defined as the third flow space S3. At the same time, the third flow space S3 may be defined as a space formed under the upper surface of the first housing 110. Accordingly, the third flow space s3 may be defined as a space formed between the third substrate 233 and the upper surface of the first housing 110.

Accordingly, it will be understood that the plurality of substrates 230 and the plurality of flow spaces S1, S2, and S3 are arranged and formed to be alternately stacked.

The fluid channel module 11 to be described later may be configured to divide the fluid introduced from the outside. The divided fluid may flow in each flow space S1, S2, and S3 through the fluid channel module 11. Accordingly, the substrate 230 and the electrical device coupled to the substrate 230 may be effectively cooled, and a detailed description thereof will be given later.

A substrate communication hole 240 is formed inside the substrate 230.

The substrate communication hole 240 is formed through the inside of the substrate 230. The substrate communication hole 240 is formed in the thickness direction of the substrate 230, that is, in the vertical direction in the illustrated embodiment, and communicates with the plurality of flow spaces S1, S2, and S3 disposed to face each other with the substrate 230 interposed therebetween.

The substrate communication hole 240 may be formed in a plurality of substrates 230, respectively. In the illustrated embodiment, the substrate 230 is provided three including the first substrate 231, the second substrate 232, and the third substrate 233. Accordingly, the substrate communication hole 240 may also be provided three including the first substrate communication holes 241, the second substrate communication holes 242, and the third substrate communication holes 243.

At this time, the first substrate communication holes 241, the second substrate communication holes 242, and the third substrate communication holes 243 communicate with each other. The fluid introduced into the housing 100 may pass through the first substrate communication hole 241, the second substrate communication hole 242, and the third substrate communication hole 243 in sequence.

The first substrate communication hole 241 is formed through the inside of the first substrate 231 in its thickness direction. The first substrate communication hole 241 communicates with the fluid channel module 11.

Specifically, the first substrate communication hole 241 communicates the divided space 320 of the fluid channel division member 300 with the duct member 400 communicating with the divided space 320 at one side facing the second space 152, that is, the lower side in the illustrated embodiment. The first substrate communication hole 241 communicates with the vortex formation member 500, specifically the first vortex formation member 500a at the other side facing the first housing 110, that is, the upper side in the illustrated embodiment.

Some of the fluid channel of the fluid divided by the fluid channel division member 300 may extend to the first substrate communication hole 241 through the divided space 320 and the duct member 400. In addition, some of the fluid channel may extend to the vortex formation member 500.

The second substrate communication hole 242 is formed through the inside of the second substrate 232 in its thickness direction. The second substrate communication hole 242 communicates with the fluid channel module 11 so that the fluid passing through the first substrate communication hole 241 may flow.

Specifically, the second substrate communication hole 242 communicates with the vortex formation member 500, specifically the first vortex formation member 500a at one side facing the second space 152, that is, the lower side in the illustrated embodiment. Accordingly, the second substrate communication hole 242 may communicate with the first substrate communication hole 241.

In addition, the second substrate communication hole 242 communicates with the vortex formation member 500, specifically the second vortex formation member 500b at the other side facing the first housing 110, that is, the upper side in the illustrated embodiment.

One portion of the fluid introduced into the first vortex formation member 500a flows out to the first flow space S1. The other portion of the fluid introduced into the first vortex formation member 500a may flow to the second vortex formation member 500b through the second substrate communication hole 242.

The third substrate communication hole 243 is formed through the inside of the third substrate 233 in its thickness direction. The third substrate communication hole 243 may communicate with the fluid channel module 11 so that the fluid passing through the second substrate communication hole 242 may flow.

Specifically, the third substrate communication hole 243 communicates with the vortex formation member 500, specifically the second vortex formation member 500b at one side facing the second space 152, that is, the lower side in the illustrated embodiment.

In addition, the third substrate communication hole 243 communicates with the first space 151 at the other side facing the first housing 110, that is, the upper side in the illustrated embodiment.

One portion of the fluid introduced into the second vortex formation member 500b flows out to the second flow space S2. The other portion of the fluid introduced into the second vortex formation member 500b may flow into the first space 151 through the third substrate communication hole 243.

In the illustrated embodiment, the first substrate communication hole 241, the second substrate communication hole 242, and the third substrate communication hole 243 are disposed to overlap in the height direction of the housing 100, that is, in the vertical direction in the illustrated embodiment.

In addition, the first substrate communication hole 241, the second substrate communication hole 242, and the third substrate communication hole 243 are disposed to overlap in the height direction of the duct member 400, the vortex formation member 500, and the housing 100, that is, in the vertical direction in the illustrated embodiment.

In this case, as will be described below, the duct member 400 extends obliquely along the front and rear directions. Accordingly, it will be understood that the first substrate communication hole 241 and the support through-hole 161 coupled with respective ends of the duct member 400 are not disposed to overlap in the vertical direction.

The arrangement method of the first substrate communication hole 241, the second substrate communication hole 242, and the third substrate communication hole 243 may be disposed in an arbitrary manner to communicate with the fluid channel module 11 to allow the fluid introduced from the outside to flow in the first to third flow spaces S1, S2, and S3.

The first substrate communication hole 241, the second substrate communication hole 242, and the third substrate communication hole 243 may be formed in an arbitrary shape capable of communicating with the fluid channel module 11. In the illustrated embodiment, the first substrate communication hole 241, the second substrate communication hole 242, and the third substrate communication hole 243 have a circular cross-section and is a disk shape formed to extend in the vertical direction.

The shape of the first substrate communication hole 241, the second substrate communication hole 242, and the third substrate communication hole 243 may be changed according to the shape of the duct member 400 or the vortex formation member 500.

The capacitor 250 supplies power necessary for the switching element 210 and the substrate 230 to operate. The capacitor 250 is electrically connected to the switching element 210 and the substrate 230.

The capacitor 250 may receive and store power by an external power source. The capacitor 250 may be electrically connected to an external power source by the terminal 140.

The capacitor 250 is accommodated in the housing 100. In the illustrated embodiment, the capacitor 250 is accommodated in the second space 152 formed in the second housing 120.

The capacitor 250 is coupled to the substrate 230, specifically, the first substrate 231 located at the lowermost side. The capacitor 250 may be electrically connected to the first substrate 231 to transmit power.

Accordingly, each component of the electrical connection unit 200, that is, the switching element 210, the substrate 230, and the capacitor 250, may be electrically connected to each other.

The capacitor 250 may be provided in plural. The plurality of capacitors 250 may be electrically connected to the terminal 140, the switching element 210, and the substrate 230, respectively.

The process of storing power in the capacitor 250 and transmitting the stored power to other components is well-known in the art, and thus detailed description will be omitted.

### 3. Description of the Configuration of the Fluid Channel Module 11 According to an Embodiment of the Present Disclosure

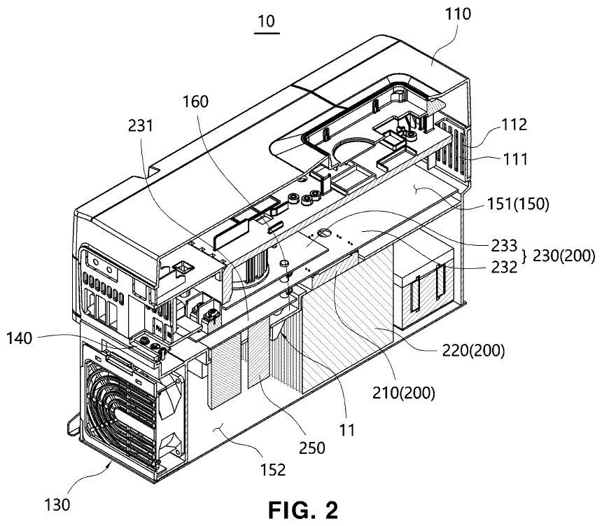

Referring again to FIGS. 2 to 5, the power device 10 according to the embodiment of the present disclosure includes the fluid channel module 11.

The fluid channel module 11 is provided in the power device 10 to form a flow of fluid introduced into the power device 10 in various forms. The introduced fluid may flow to various positions through the fluid channel module 11. In addition, the introduced fluid may flow in a vortex form by the fluid channel module 11. Accordingly, cooling of the components accommodated in the power device 10 may be effectively performed.

The fluid channel module 11 is accommodated in the housing 100. Specifically, one portion of the fluid channel module 11 is accommodated in the first housing 110 and the other portion of the fluid channel module 11 is accommodated in the second housing 120. Referring to FIGS. 3 to 4, the fluid channel division member 300 and the duct member 400 are located in the second space 152, and the vortex formation member 500 is located in the first space 151.

The fluid channel module 11 is coupled to other components of the power device 10. In the illustrated embodiment, the fluid channel module 11 is coupled to the support plate 160 and the substrate 230, respectively.

The fluid channel module 11 communicates with various spaces formed inside the power device 10. In the illustrated embodiment, the fluid channel module 11 communicates with the first space 151, the second space 152, the first flow space S1, the second flow space S2, and the third flow space S3, respectively.

Accordingly, the fluid introduced from the outside into the second space 152 may flow along the fluid channel module 11 and flow into the other spaces 151, S1, S2, and S3. The detailed description of the fluid formed by the fluid channel module 11 will be given later.

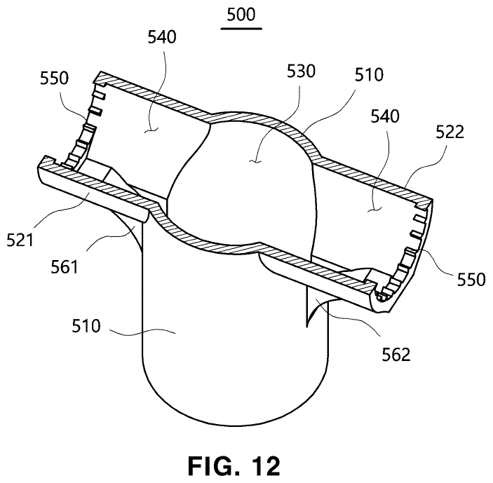

Hereinafter, the fluid channel module 11 according to an embodiment of the present disclosure will be described in detail with reference to FIGS. 2 to 5 and 6 to 13.

In the illustrated embodiment, the fluid channel module 11 includes a fluid channel division member 300, a duct member 400, and a vortex formation member 500. The fluid channel division member 300, the duct member 400, and the vortex formation member 500 communicate with each other.

The fluid channel division member 300 divides the fluid introduced into the housing 100 from the outside. The fluid channel division member 300 is located inside the second housing 120.

The fluid channel division member 300 may communicate with the second space 152 such that a portion of the fluid flowing in the second space 152 may be divided and flowed to the fluid channel division member 300. In this case, the transfer force for the fluid to be introduced into the second space 152 from the outside is provided by the blower 130 as described above.

The fluid channel division member 300 is coupled to the support plate 160. The fluid channel division member 300 communicates with the support through-hole 161 formed inside the support plate 160. The divided fluid may pass through the support through-hole 161 through the fluid channel division member 300.

In the illustrated embodiment, the fluid channel division member 300 is located between the heat dissipation member 220 and the capacitor 250. In addition, the fluid channel division member 300 is coupled to the lower side of the support plate 160.

The position of the fluid channel division member 300 may be disposed at an arbitrary position to divide the fluid introduced into the second space 152 and guide the divided fluid to the support through-hole 161, and may be coupled to an arbitrary member.

The fluid channel division member 300 communicates with the duct member 400. The fluid divided by the fluid channel division member 300 may pass through the fluid channel division member 300 and the support through-hole 161 and flow to the duct member 400.

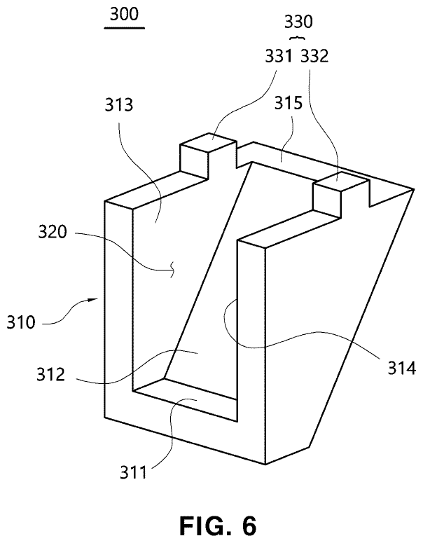

Referring to FIG. 6, the fluid channel division member 300 according to the illustrated embodiment includes a dividing body 310, a divided space 320, and a coupling protrusion 330.

The dividing body 310 forms a body of the fluid channel division member 300. The division body 310 substantially performs a role of dividing the fluid flowing in the second space 152.

The dividing body 310 is coupled to the support plate 160. In an embodiment, the dividing body 310 may be tightly coupled to the support plate 160. Accordingly, the divided fluid may flow toward the duct member 400 without returning to the second space 152 again.

The dividing body 310 may be an arbitrary shape capable of dividing the fluid introduced into the second space 152 and guiding it toward the duct member 400. In the illustrated embodiment, the dividing body 310 is formed to have one side opposite to the blower 130, that is, a rear side surface inclined.

Therefore, In the above embodiment, the fluid divided by the dividing body 310 may flow along the rear side surface formed obliquely toward the support plate 160, and may proceed smoothly to the duct member 400.

A divided space 320 is formed inside the dividing body 310. The dividing body 310 is formed to at least partially surround the divided space 320. In the illustrated embodiment, the dividing body 310 is formed to surround the divided space 320 on the left, right, lower and rear sides.

The dividing body 310 is continuous with the coupling protrusion 330. The division body 310 may be coupled to the support plate 160 by the coupling protrusion 330.

In the illustrated embodiment, the dividing body 310 includes a first dividing surface 311, a second dividing surface 312, a third dividing surface 313, a fourth dividing surface 314, and a coupling surface 315.

The first dividing surface 311 forms one surface of the dividing body 310. The first dividing surface 311 is disposed to surround the divided space 320 on one side. In the illustrated embodiment, the first dividing surface 311 forms a lower surface of a front of the dividing body 310.

The first dividing surface 311 partially surrounds the divided space 320. In the illustrated embodiment, the first dividing surface 311 is disposed to surround the lower side of the front of the divided space 320.

The first dividing surface 311 may be formed to extend along its width direction and longitudinal direction. In the illustrated embodiment, the first dividing surface 311 has a shorter extension length in the front and rear directions than in the left and right directions.

The first dividing surface 311 may extend in the flow direction of the fluid, that is, in the front and rear directions, while forming a predetermined angle. In an embodiment, the first dividing surface 311 may extend in the front and rear directions to be parallel to the substrate 230.

The first dividing surface 311 forms a predetermined angle and is continuous with the second dividing surface 312.

The second dividing surface 312 forms another surface of the dividing body 310. The second dividing surface 312 is disposed to surround the divided space 320 on another side. In the illustrated embodiment, the second dividing surface 312 forms a rear side surface of the dividing body 310.

The second dividing surface 312 partially surrounds the divided space 320. In the illustrated embodiment, the second dividing surface 312 is disposed to surround the rear side of the divided space 320.

The second dividing surface 312 guides the fluid introduced into the divided space 320. The fluid entering the divided space 320 may flow along the second dividing surface 312 and may flow toward the support through-hole 161 and the duct member 400.

The second dividing surface 312 may be formed to extend along its width direction and longitudinal direction. In the illustrated embodiment, the second dividing surface 312 has a longer extension length in the front and rear directions than the extension length in the left and right directions.

The second dividing surface 312 may extend in the flow direction of the fluid, that is, in the front and rear directions, while forming a predetermined angle. In the embodiment shown, the second dividing surface 312 extends obliquely toward the upper side of the rear. That is, the second dividing surface 312 may be defined as an inclined surface for guiding the introduced fluid.

The width directions of the first dividing surface 311 and the second dividing surface 312 are coupled to the third dividing surface 313 and the fourth dividing surface 314, respectively.

The third dividing surface 313 and the fourth dividing surface 314 form different another surfaces of the dividing body 310, respectively. The third dividing surface 313 and the fourth dividing surface 314 are disposed to surround the divided space 320 on different another side. In the illustrated embodiment, the third dividing surface 313 and the fourth dividing surface 314 form the left and right side surfaces of the dividing body 310, respectively.

The third dividing surface 313 and the fourth dividing surface 314 partially surround the divided space 320. In the illustrated embodiment, the third dividing surface 313 and the fourth dividing surface 314 are disposed to surround the left and right sides of the divided space 320, respectively.

The third dividing surface 313 and the fourth dividing surface 314 guide the fluid introduced into the divided space 320 not to be randomly separated in the width direction, that is, the left and right directions in the illustrated embodiment. The fluid entering the divided space 320 may be guided to the third dividing surface 313 and the fourth dividing surface 314 and may flow toward the duct member 400 without flowing out in the width direction thereof.

The third dividing surface 313 and the fourth dividing surface 314 may be an arbitrary shape capable of coupling to the first dividing surface 311 and the second dividing surface 312 and surrounding the divided space 320. In the illustrated embodiment, the third dividing surface 313 and the fourth dividing surface 314 have a trapezoidal shape in which the shape of the cross-section is parallel to the upper side and the lower side.

At this time, the cross-section of the third dividing surface 313 and the cross-section of the fourth dividing surface 314 are formed such that the extension length of the upper side is longer than the extension length of the lower side. Accordingly, it will be understood that the rear edge of the cross-section of the third dividing surface 313 and the fourth dividing surface 314 extend obliquely upward.

The coupling surface 315 is a portion where the fluid channel division member 300 is in contact with the support plate 160 or the duct member 400. The coupling surface 315 may be tightly coupled to the support plate 160 or the duct member 400. Accordingly, there is no gap between the coupling surface 315 and the support plate 160 or the duct member 400, and the fluid introduced into the divided space 320 may flow toward the duct member 400.

The coupling surface 315 may be formed on one side of the dividing body 310 facing the support plate 160 or the duct member 400. In the illustrated embodiment, the coupling surface 315 forms an upper surface of the dividing body 310. In the above embodiment, the coupling surface 315 may extend parallel to the support plate 160.

The coupling surface 315 may be formed to extend along an upper end of the dividing body 310. In other words, the coupling surface 315 forms an upper surface of the dividing body 310. In the above embodiment, the coupling surface 315 may be formed to have a shape of a bracket.

In the above embodiment, a pair of portions of the coupling surface 315 may be disposed to face each other with the divided space 320 interposed therebetween. In the illustrated embodiment, a portion located on the left side and a portion located on the right side of the coupling surface 315 are disposed to face each other with the divided space 320 interposed therebetween.

The coupling protrusion 330 is located in the pair of portions.

The divided space 320 is a space through which the divided fluid flows by being introduced into the second space 152. The divided space 320 may communicate with the second space 152 to introduce the divided fluid.

The divided space 320 communicates with the support through-hole 161 and the duct member 400. The fluid introduced into the divided space 320 may pass through the support through-hole 161 and flow into the duct member 400.

The divided space 320 is formed inside the dividing body 310. Specifically, the divided space 320 may be surrounded by a plurality of surfaces constituting the dividing body 310. As described above, the divided space 320 is partially surrounded by the first to fourth dividing surfaces 311, 312, 313, and 314.

The divided space 320 communicates with the outside. The direction in which the fluid is introduced into the second space 152 among the portions of the divided space 320, and the front side in the illustrated embodiment, are formed open and communicate with the second space 152. The fluid in the second space 152 may flow to the divided space 320 through the front side.

In addition, the direction in which the fluid outflows from the divided space 320 among the portions of the divided space 320, that is, the upper side in the illustrated embodiment, is also formed open and communicates with the support through-hole 161 and the duct hollow 420. The fluid flowing in the divided space 320 may flow to the support through-hole 161 and the duct hollow 420 through the upper side.

It will be understood that the fluid introduced into the divided space 320 moves obliquely upward due to the shape of the second dividing surface 312.

The divided space 320 may have an arbitrary shape in which the fluid may flow therein. As described above, in the illustrated embodiment, the divided space 320 is surrounded by the first dividing surface 311 on the lower side of the front and the second dividing surface 312 on the rear. The left and right sides of the divided space 320 are surrounded by the third partition surface 313 and the fourth partition surface 314, respectively.

Accordingly, the fluid introduced into the second space 152 may flow into the divided space 320 toward the front side thereof, and then may flow to the upper side obliquely, and may flow to the support through-hole 161 and the duct hollow 420 through the upper side.

The coupling protrusion 330 is a portion where the fluid channel division member 300 is coupled to the support plate 160. The coupling protrusion 330 is formed to protrude in the direction from the dividing body 310 toward the support plate 160, that is, upward in the illustrated embodiment.

The coupling protrusion 330 is located on one side of the portion of the dividing body 310 toward the support plate 160. In the illustrated embodiment, the coupling protrusion 330 is located on the coupling surface 315 located on the upper side of the dividing body 310.

In an embodiment, the coupling protrusion 330 may be fitted and coupled to the support plate 160. In the above embodiment, a groove for inserting the coupling protrusion 360 may be recessed or penetrated inside the support plate 160.

The coupling protrusion 330 may be provided in an arbitrary shape capable of being coupled to the support plate 160. In the illustrated embodiment, the coupling protrusion 330 has a rectangular cross-section in the horizontal direction and is formed to have a height in the vertical direction.

The coupling protrusion 330 may be provided in plural. The plurality of coupling protrusions 330 may be spaced apart from each other and may be coupled to the support plate 160 at different positions.

In the illustrated embodiment, the coupling protrusion 330 is provided in a pair, including a first coupling protrusion 331 positioned on the left side and a second coupling protrusion 332 positioned on the right side. The first coupling protrusion 331 and the second coupling protrusion 332 are disposed to be spaced apart from each other in the left and right directions. In other words, the pair of coupling protrusions 330 are disposed to face each other in the width direction of the divided space 320 with the divided space 320 interposed therebetween.

Therefore, since the plurality of coupling protrusions 330 are coupled to the support plate 160 at the plurality of positions, the coupling state between the fluid channel division member 300 and the support plate 160 may be stably maintained.

The duct member 400 communicates the fluid channel division member 300 with the vortex formation member 500. The fluid divided by the fluid channel division member 300 and passing through the support through-hole 161 may flow to the duct member 400.

The duct member 400 is positioned between the support plate 160 and the substrate 230. The duct member 400 is coupled to the support plate 160 and the substrate 230, respectively. In the illustrated embodiment, a lower end of the duct member 400 is coupled to the support plate 160, and an upper end of the duct member 400 is coupled to the substrate 230.

The duct member 400 communicates with the fluid channel division member 300 and the vortex formation member 500, respectively.

Specifically, the duct member 400 communicates with the divided space 320 through the support through-hole 161. The fluid introduced into the second space 152 may flow into the duct member 400 via the divided space 320 and the support through-hole 161 in sequence. The inside of the duct member 400 communicates with the support through-hole 161 and the divided space 320, respectively.

Further, the duct member 400 communicates with the vortex hollows 530, and 540 formed in the vortex formation member 500 through the substrate communication hole 240. The fluid introduced into the duct member 400 may flow to the vortex hollows 530, and 540 through the substrate communication hole 240. The inside of the duct member 400 communicates with the substrate communication hole 240 and the vortex hollows 530, and 540, respectively.

The duct member 400 may extend at a predetermined angle with respect to the vertical direction. In the illustrated embodiment, the duct member 400 has its lower end located biased toward the front side and its upper end located biased toward the rear side. In other words, in the illustrated embodiment, the duct member 400 is formed in an “S” shape in its cross-section.

Due to the shape of the duct member 400, the inner surface of the duct member 400 may be formed to have a slope corresponding to the second dividing surface 312 of the fluid channel division member 300. In an embodiment, the inner surface of the duct member 400 may be formed to have the same slope as the second dividing surface 312 with respect to the horizontal direction.

Accordingly, the flow resistance inside the duct member 400 is minimized, so that the fluid may flow smoothly.

The duct member 400 may be formed of a flexible material. This is to prevent random separation from the support plate 160 or the substrate 230 by vibration generated as the power device 10 is operated.

The duct member 400 may be formed of an electrically insulating material. This is to prevent randomly electrical connection between the support plate 160 to which the duct member 400 is coupled and the substrate 230.

The duct member 400 may be formed of a thermally insulating material. This is to prevent heat transfer between the support plate 160 and the substrate 230.

In an embodiment, the duct member 400 may be made of a rubber or silicon material.

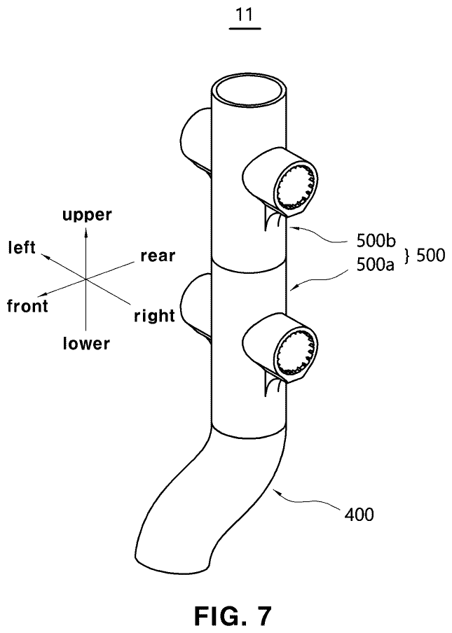

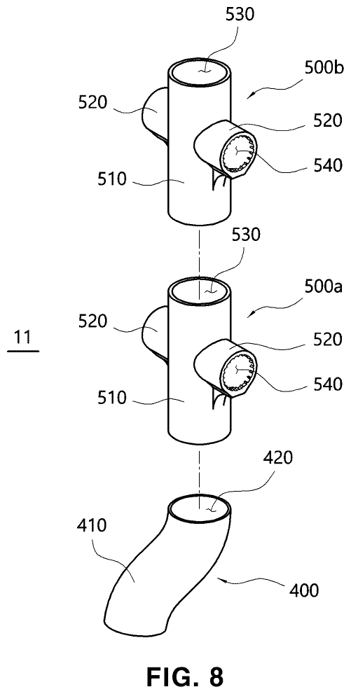

For convenience of understanding, in FIGS. 7 to 8, the duct member 400 is illustrated as being directly coupled to the vortex formation member 500. However, it will be understood that a plurality of substrates 230 may be coupled between the duct member 400 and the plurality of vortex formation members 500.

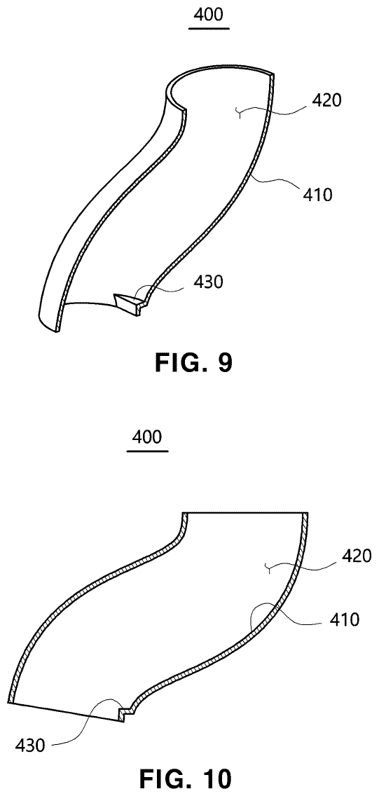

In the embodiment shown in FIGS. 9 and 10, the duct member 400 includes a duct body 410, a duct hollow 420, and a duct corner 430.

The duct body 410 forms a body of the duct member 400. The duct body 410 is a portion where the duct member 400 is coupled to the support plate 160 and the substrate 230. The duct body 410 extends between the support plate 160 and the substrate 230. As described above, the support plate 160 and the substrate 230 are disposed to be spaced apart from each other in the vertical direction and be stacked. Accordingly, it may be said that the duct body 410 extends in the vertical direction.

Among the ends of the duct body 410 in the extension direction, one end toward the support plate 160, that is, the lower end in the illustrated embodiment, may be coupled to the support plate 160. In an embodiment in which the support through-hole 161 is sufficiently large, the one end of the duct body 410 may be directly coupled to the coupling surface 315 of the fluid channel division member 300.

The other end of the duct body 410 in the extension direction facing the substrate 230, that is, the upper end in the illustrated embodiment, may be coupled to the substrate 230, specifically, the first substrate 231 located lowermost among the plurality of substrates 230.

At this time, the duct body 410 may cover the support through-hole 161 and the substrate communication hole 240 and may be coupled to the support plate 160 and the substrate 230, respectively.

Inside the duct body 410, a duct hollow 420 is formed. The inner surface of the duct body 410 extends while surrounding the duct hollow 420 in the radial direction. As described above, the inner surface of the duct body 410 is formed to extend obliquely upward in a direction from the front side to the rear side.

In other words, the inner surface of the duct body 410 is formed to extend obliquely with respect to the support plate 160 or the first substrate 231.

In an embodiment, a separate bending part may not be formed on the inner surface of the duct body 410. In other words, the inner surface of the duct body 410 may extend obliquely but smoothly. Therefore, the flow resistance of the fluid inside the duct body 410 is minimized, so that the fluid may flow smoothly.

The duct hollow 420 is a space in which the divided fluid flows through the fluid channel division member 300. The duct hollow 420 is formed inside the duct body 410. The duct hollow 420 is formed to extend in a direction in which the duct body 410 extends, that is, to be inclined upward from the front side to the rear side in the illustrated embodiment.

Each end of the duct hollow 420 in the extending direction, that is, the upper end and the lower end in the illustrated embodiment are formed open, respectively. In other words, the duct hollow 420 is formed through the inside of the duct body 410 along the extension direction of the duct body 410.

The duct hollow 420 communicates with the divided space 320 and the vortex hollows 530, and 540, respectively.

Specifically, one end of each end of the duct hollow 420 in the direction of extension facing the fluid channel division member 300, that is, the lower end in the illustrated embodiment, communicates with the divided space 320. In this case, the one end of the duct hollow 420 may communicate with the divided space 320 by the support through-hole 161 formed in the support plate 160.

Among the ends of the duct hollow 420 in the extension direction, the other end toward the substrate 230 or the vortex formation member 500, that is, the upper end in the illustrated embodiment, communicates with the vortex hollows 530, and 540. In this case, the other end of the duct hollow 420 may communicate with the vortex hollows 530, and 540 through the substrate 230, specifically, the first substrate communication hole 241 formed inside the first substrate 231.

The duct corner 430 is a portion where the duct member 400 is coupled to the fluid channel division member 300. The duct corner 430 is formed on the inner and outer surfaces of the duct body 410, respectively.

In the illustrated embodiment, the duct corner 430 includes a first portion extending horizontally toward the duct hollow 420 and a second portion continuous with the first portion and extending vertically toward the support plate 160. In other words, in the illustrated embodiment, the duct corner 430 has a rectangular one corner shape in cross-section.

A coupling surface 315 of the fluid channel division member 300 may be coupled to the duct corner 430. In an embodiment, the duct corner 430 and the coupling surface 315 may be tightly coupled to block any communication between the duct hollow 420 and the outside.

In another embodiment, the duct corner 430 may be coupled to the support plate 160. In other words, in the above embodiment, the duct member 400 may be coupled to the fluid channel division member 300 via the support plate 160. In this case, the support plate 160 may be provided with a component for coupling with the duct edge 430, for example, a protrusion.

In either case, it is sufficient to prevent the fluid flowing into the divided space 320 and passing through the support through-hole 161 from flowing to a position other than the duct hollow 420.

The duct member 400 is coupled to the vortex formation member 500. The duct member 400 communicates with the vortex formation member 500.

The vortex formation member 500 functions as a passageway through which the fluid passing through the duct member 400, that is, the fluid divided by the fluid channel division member 300, is discharged between the plurality of substrates 230. By the vortex formation member 500, a fluid for cooling may flow in the space between the plurality of substrates 230, that is, in the first to third flow spaces S1, S2, and S3.

Accordingly, the substrate 230 without a separate heat dissipation member may also be effectively cooled.

Referring again to FIG. 4, the vortex formation member 500 is positioned between a plurality of substrates 230. As described above, the plurality of substrates 230 are stacked by being spaced apart from each other in the vertical direction. Therefore, it may be said that the vortex formation member 500 is alternately disposed with a plurality of substrates 230 in the vertical direction.

The vortex formation member 500 is connected to a plurality of substrates 230, respectively. The vortex formation member 500 extends between a plurality of substrates 230 stacked to be spaced apart from each other. In the illustrated embodiment, the vortex formation member 500 is formed to extend in the vertical direction.

Among the ends of the vortex formation member 500 in the extended direction, one end toward the first housing 110, that is, the upper end in the illustrated embodiment, is coupled to the substrate 230 located relatively above. Among the ends of the vortex formation member 500 in the extended direction, the other end toward the second housing 120, that is, the lower end in the illustrated embodiment, is coupled to the substrate 230 located relatively below.

The vortex formation member 500 may be formed of an electrically insulating material. The vortex formation member 500 is coupled to different substrates 230, so that any electrical conduction between the substrates 230 is prevented.

The vortex formation member 500 may be formed of a thermally insulating material. The fluid discharged from the vortex formation member 500 to the first to third flow spaces S1, S2, and S3 is configured to perform cooling of the substrate 230. Accordingly, the vortex formation member 500 is preferably made of a thermally insulating material so as to be maintained at a lower temperature than the first to third flow spaces S1, S2, and S3 and the substrate 230.

The vortex formation member 500 communicates with the duct member 400. Specifically, the other end of the vortex formation member 500, that is, the lower end in the illustrated embodiment communicate with the duct hollow 420 through the substrate communication hole 240.

The vortex formation member 500 communicates with the first to third flow spaces S1, S2, and S3. The fluid flowing into the vortex formation member 500 may be discharged to the first to third flow spaces S1, S2, and S3.

The vortex formation member 500 may be provided in plural. The plurality of vortex formation members 500 may be disposed in a direction in which the plurality of substrates 230 are spaced apart from each other and stacked, that is, in a vertical direction in the illustrated embodiment.

The plurality of vortex formation members 500 may communicate with each other. Specifically, the vortex formation member 500 located relatively above has its lower end communicated with the upper end of the vortex formation member 500 positioned relatively below by the substrate communication hole 240.

In the illustrated embodiment, two vortex forming members 500 include a first vortex forming member 500a and a second vortex forming member 500b.

The first vortex formation member 500a is positioned between the first substrate 231 and the second substrate 232. Therefore, it may be said that the first vortex formation member 500a is located in the first flow space S1.

The lower end of the first vortex formation member 500a is coupled to the first substrate 231 and communicates with the first substrate communication hole 241. The upper end of the first vortex formation member 500a is coupled to the second substrate 232 and communicates with the second substrate communication hole 242.

The second vortex formation member 500b is positioned between the second substrate 232 and the third substrate 233. Therefore, it may be said that the second vortex formation member 500b is located in the second flow space S2.

The lower end of the second vortex formation member 500b is coupled to the second substrate 232 and communicates with the second substrate communication hole 242. By the communication, the first vortex formation member 500a and the second vortex formation member 500b may communicate with each other.

In addition, the upper end of the second vortex formation member 500b is coupled to the third substrate 233 and communicates with the third substrate communication hole 243. By the communication, the second vortex formation member 500b and the third flow space S3 may communicate with each other.

The number of vortex formation members 500 may be changed. In this case, the number of vortex formation members 500 may be changed corresponding to the number of substrates 230. That is, as described above, the vortex formation member 500 is positioned between a pair of substrates 230 disposed adjacent to each other. Therefore, it will be understood that the vortex formation member 500 may be provided less than the number of substrates 230.

Meanwhile, the number of vortex formation members 500 disposed in each flow space S1, S2, and S3 may be changed. In the illustrated embodiment, it is illustrated that a singular number of vortex formation members 500 are provided in the first flow space S1 and the second flow space S2. Alternatively, a plurality of vortex formation members 500 may be disposed in each flow space S1, S2, and S3.

In the above embodiment, it is preferable that virtual straight lines extending the second vortex hollow 540 to be described later are disposed not to intersect with each other in the flow spaces S1, S2, and S3 so as not to cause interference between the fluids discharged from the plurality of vortex formation members 500.

The first vortex formation member 500a and the second vortex formation member 500b differ in the components to be coupled and the components to be communicated, but the structures thereof are the same. Accordingly, in the following description, the description of the portions in which the first vortex formation member 500a and the second vortex formation member 500b are common to each other will be collectively referred to as the vortex formation member 500.

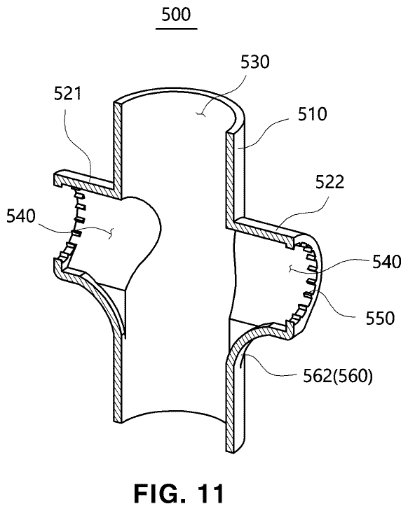

Referring to FIGS. 11 to 13, the vortex formation member 500 according to the illustrated embodiment includes a vortex body 510, a vortex arm 520, a first vortex hollow 530, a second vortex hollow 540, a vortex protrusion 550, and a vortex rib 560.

The vortex body 510 forms a portion of the exterior of the vortex formation member 500. The vortex body 510 extends between a pair of substrates 230 positioned adjacent to each other. In the illustrated embodiment, the vortex body 510 is formed to extend in the vertical direction.

One end of the vortex body 510 in the extension direction, that is, an upper end in the illustrated embodiment, are coupled to the substrate 230 located relatively above the pair of substrates 230. The other end portion of the vortex body 510 in the extension direction, that is, a lower end in the illustrated embodiment, are coupled to the substrate 230 located relatively below the pair of substrates 230.

In this case, each end of the vortex body 510 may cover the substrate communication hole 240 and be coupled to each substrate 230.

The vortex body 510 may have a first vortex hollow 530 formed therein and may be an arbitrary shape in which fluid may flow. In the illustrated embodiment, the vortex body 510 is circular in its outer circumference, and is formed to have a ring-shaped cross-section through which the first vortex hollow 530 is formed.

The vortex body 510 is coupled to the vortex arm 520. By the coupling, the first vortex hollow 530 may communicate with the second vortex hollow 540 formed inside the vortex arm 520.

The vortex rib 560 is formed on a portion where the vortex arms 520 are coupled to the vortex body 510.

The vortex arm 520 forms another portion of the exterior of the vortex formation member 500. The vortex arm 520 extends in a direction different from that of the vortex body 510. In the illustrated embodiment, the vortex arm 520 is formed to extend in a horizontal direction.

Each end of the vortex arm 520 in the extended direction is formed open and communicates with the outside. By the communication, the vortex formation member 500 may communicate with the first flow space S1 and the second flow space S2. The fluid flowing to the vortex formation member 500 may be discharged to the first flow space S1 or the second flow space S2 through the vortex arm 520.

The vortex arm 520 may be provided in an arbitrary form in which a second vortex hollow 540 is formed therein to discharge the fluid introduced into the vortex formation member 500 to the first flow space S1 or the second flow space S2. In the illustrated embodiment, the vortex arm 520 is circular, and is formed to have a ring-shaped cross-section through which the second vortex hollow 540 is formed.

The vortex arm 520 may be formed to extend in an arbitrary direction capable of discharging the fluid to the first flow space S1 or the second flow space S2. Referring again to FIGS. 2 to 5, the vortex arm 520 is formed to extend in the width direction of the housing 100, that is, in the left and right directions.

Alternatively, the vortex arm 520 may extend in the longitudinal direction, that is, the front and rear directions of the housing 100, or may extend in the diagonal direction. In this case, the extension direction of the vortex arm 520 may be changed according to various configurations disposed in the first flow space S1 or the second flow space S2, for example, the arrangement of an arbitrary configuration that generates heat, such as the substrate 230 or the switching element 210 coupled to the substrate 230.

In either case, it is sufficient if the fluid discharged from the vortex arm 520 flows in the first flow space S1 or the second flow space S2 and may cool various components.

The vortex arm 520 may be provided in plural. The plurality of vortex arms 520 may be coupled to the vortex body 510 at different positions. In the illustrated embodiment, the vortex arms 520 includes a first arm 521 disposed on the left side of the vortex body 510 and a second arm 522 disposed on the right side of the vortex body 510. In the above embodiment, the first arm 521 and the second arm 522 are disposed to face each other with the vortex body 510 interposed therebetween.

In an embodiment, the vortex arm 520 may be provided in a plurality of pairs and may extend in different directions. In the illustrated embodiment, the vortex arm 520 is provided in a pair formed to extend in the left and right directions, but may be provided with an additional pair of vortex arms 520 formed to extend in the front and rear directions, the diagonal directions, or the like.

The vortex rib 560 is formed on the portion where the vortex arm 520 are coupled to the vortex body 510. In addition, a vortex protrusion 550 is formed on an inner surface adjacent to each end of the vortex arm 520.

The first vortex hollow 530 is formed through the inside of the vortex formation member 500. The first vortex hollow 530 communicates with the duct member 400. The fluid passing through the duct member 400 may flow into the vortex formation member 500 through the first vortex hollow 530.

The first vortex hollow 530 extends along the extension direction of the vortex body 510. Each end of the first vortex hollow 530 in the extended direction is formed open and communicates with the outside. In the illustrated embodiment, the first vortex hollow 530 is formed to extend in the vertical direction in the same manner as the vortex body 510. The upper end and the lower end of the first vortex hollow 530 are formed open, respectively.

In the case of the first vortex hollow 530 formed in the first vortex formation member 500a, a lower end thereof communicates with the duct hollow 420 by the first substrate communication hole 241. In addition, in the above case, an upper end of the first vortex hollow 530 communicates with a lower end of the second vortex formation member 500b by the second substrate communication hole 242.

Similarly, in the case of the first vortex hollow 530 formed in the second vortex formation member 500b, the lower end thereof communicates with the upper end of the first vortex hollow 530 formed in the first vortex formation member 500a by the second substrate communication hole 242. In the above case, the upper end of the first vortex hollow 530 communicates with the third flow space S3 by the third substrate communication hole 243.

The first vortex hollow 530 communicates with the second vortex hollow 540.

The second vortex hollow 540 forms a path by which the fluid introduced through the first vortex hollow 530 is discharged to the respective flow spaces S1 and S2. The second vortex hollow 540 communicates with the first vortex hollow 530.

The second vortex hollow 540 is formed through the inside of the vortex formation member 500. The second vortex hollow 540 extends along the extension direction of the vortex arm 520. Each end of the second vortex hollow 540 in the extension direction is formed open and communicates with the outside. In the illustrated embodiment, the second vortex hollow 540 is formed to extend in the left and right directions in the same manner as the vortex arm 520. The second vortex hollow 540 extends across the first arm 521 and the second arm 522.

As described above, a vortex protrusion 550 is formed on the inner surface of the vortex arm 520 surrounding each end of the second vortex hollow 540.

The vortex protrusion 550 forms the flow of the fluid discharged from the second vortex hollow 540 toward the respective flow spaces S1, and S2 as a vortex. The fluid may flow in a spiral fashion by the vortex protrusion 550 and enter the flow spaces S1, and S2.

Accordingly, the contact area between the fluid and the substrate 230 may be increased, and the heat exchange between them may be activated. As a result, the substrate 230 may be effectively cooled by the introduced fluid.

The vortex protrusion 550 is formed on the inner surface of the vortex arm 520. In the illustrated embodiment, the vortex protrusion 550 is formed on the inner surface of the vortex arm 520 adjacent to an end of the vortex arm 520.

The vortex protrusion 550 may be provided in an arbitrary form capable of forming the flow of the fluid discharged from the second vortex hollow 540 as a vortex. In the illustrated embodiment, the vortex protrusion 550 is in a protrusion shape formed to extend toward the radially inside of the vortex arm 520.

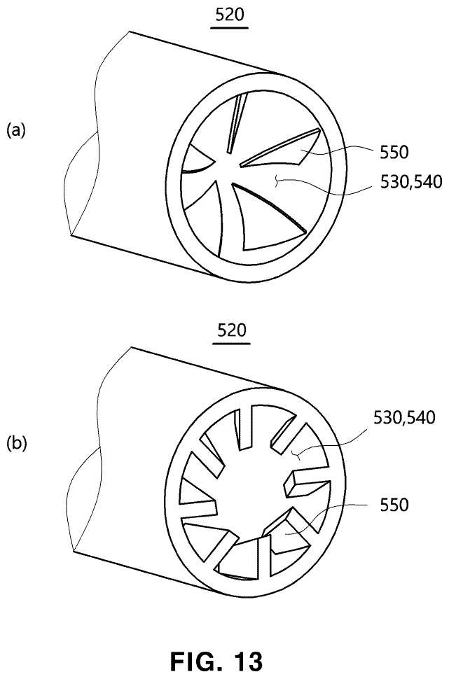

Referring to FIG. 13, various modified examples of the vortex protrusion 550 are illustrated.

Referring to FIG. 13(a), the vortex protrusion 550 may be provided in the shape of a blade. In the above embodiment, the vortex protrusion 550 may extend in a spiral shape from the radially outside of the vortex hollows 530, and 540 toward the inside. Accordingly, the flow of the fluid discharged through the space between the vortex protrusion 550 may be formed as a vortex.

Referring to FIG. 13(b), the vortex protrusion 550 may be provided in a polygonal shape extending obliquely. In the above embodiment, the vortex protrusion 550 may be formed to have a wing shape, and may extend from the radially outside of the vortex hollows 530, and 540 toward the inside. Accordingly, the flow of the fluid discharged through the space between the vortex protrusions 550 may be formed as a vortex.

Alternatively, the vortex protrusion 550 may be formed as a protrusion or groove in the shape of a rifling mark.

The vortex protrusion 550 may be provided in plural. The plurality of vortex protrusions 550 may be disposed to be spaced apart from each other along the inner surface of the vortex arm 520. In the illustrated embodiment, the plurality of vortex protrusions 550 are disposed to be spaced apart from each other along an inner circumference of the vortex arm 520.

The vortex protrusions 550 may be provided as a plurality of groups. The vortex protrusions 550 of the plurality of groups may be disposed at different positions to form a flow of fluid discharged through each end of the second vortex hollow 540 as a vortex. In the illustrated embodiment, the vortex protrusion 550 is provided with a pair of groups and is disposed adjacent to each end of a direction in which the vortex arm 520 extends.

The vortex rib 560 reinforces a coupling state of the vortex body 510 and the vortex arm 520. The vortex rib 560 is formed on a portion where the vortex body 510 is connected to the vortex arm 520. In the illustrated embodiment, the vortex rib 560 is located adjacent to the outer circumference of the vortex body 510 on the lower side of the vortex arm 520.

The vortex rib 560 may be formed in plural. The plurality of vortex ribs 560 may be located adjacent to the plurality of vortex arms 520, respectively. In the illustrated embodiment, two vortex ribs 560 may be provided and positioned adjacent to the first arm 521 and the second arm 522, respectively.

A groove (reference numeral not given) may be formed radially inside a portion where the vortex rib 560 is formed. The groove smoothly connects the inner surface of the vortex body 510 surrounding the first vortex hollow 530 to the inner surface of the vortex arm 520 surrounding the second vortex hollow 540.

Accordingly, the fluid introduced into the first vortex hollow 530 may easily flow into the second vortex hollow 540.

### 4. Description of the Configuration of a Fluid Channel of a Fluid Formed Inside the Power Device 10 According to an Embodiment of the Present Disclosure

The power device 10 according to the embodiment of the present disclosure described above includes the fluid channel module 11. The fluid channel module 11 forms a fluid channel through which fluid may flow toward the substrate 230 that is difficult to be directly cooled by the heat dissipation member 220. Accordingly, the fluid introduced for cooling the components of the power device 10 may flow in the substrate 230 or the space between the substrate 230, and exchange heat with the substrate 230.

As a result, even when the heat dissipation member 220 is not provided adjacent to the substrate 230, the substrate 230 and the elements coupled to the substrate 230 may be effectively cooled. Therefore, the cooling efficiency of the power device 10 may be improved, and operation reliability of the power device 10 may be improved.

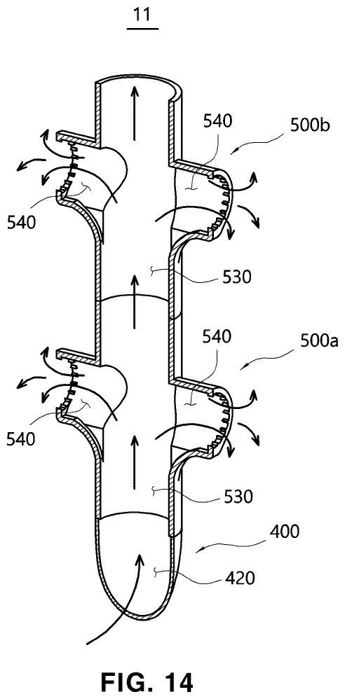

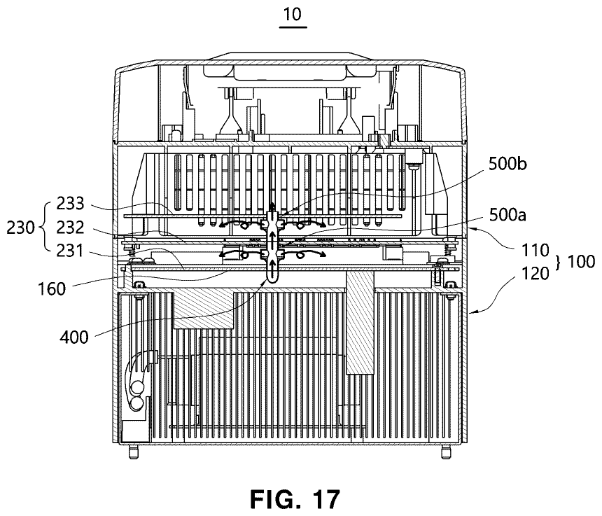

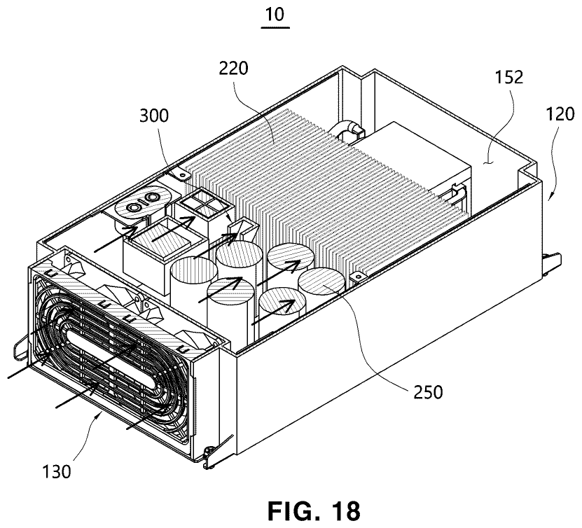

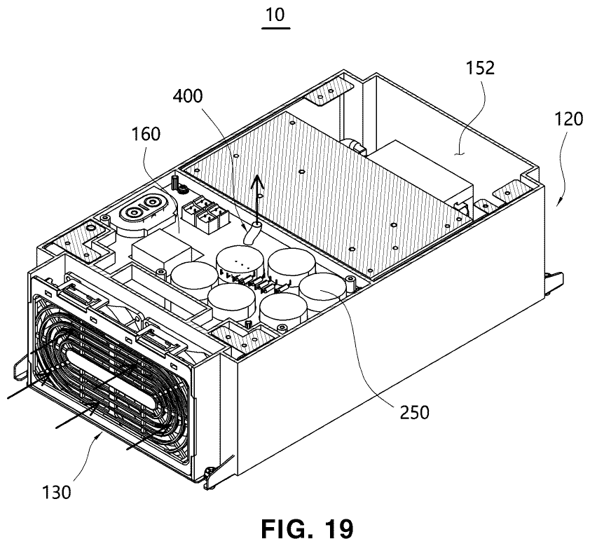

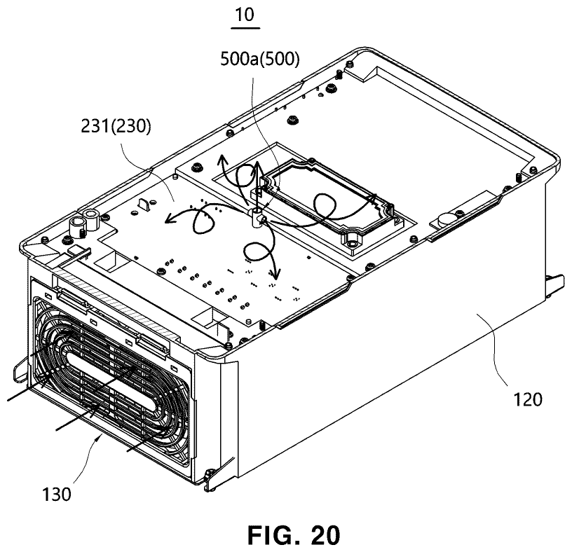

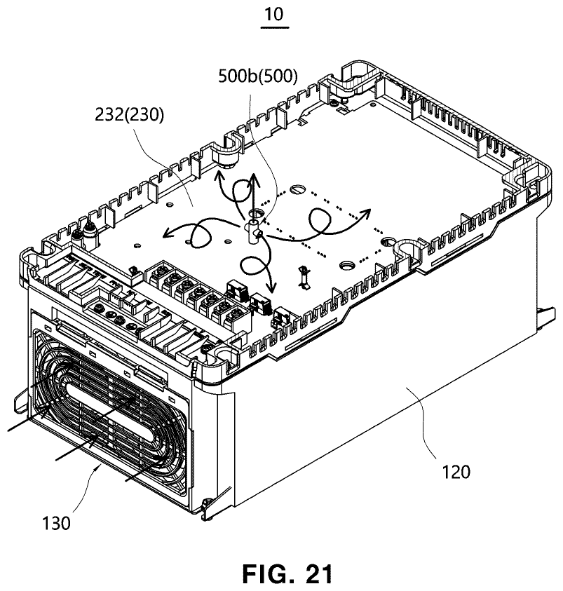

Hereinafter, a fluid channel of a fluid formed inside the power device 10 according to an embodiment of the present disclosure will be described with reference to FIGS. 14 to 21. In the illustrated embodiment, the fluid channel of the fluid is indicated by an arrow. As described above, it will be understood that the fluid channel of the fluid described below is formed by the fluid introduced by the operation of the blower 130.

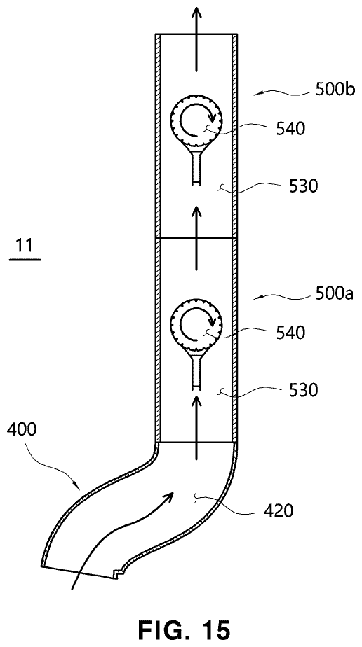

First, referring to FIGS. 14 and 15, a fluid channel of a fluid formed inside the fluid channel module 11 according to an embodiment of the present disclosure is illustrated. For convenience of understanding, illustrations of the fluid channel division member 300, the support plate 160, and each substrate 230 are omitted.

The fluid introduced into the divided space 320 of the fluid channel division member 300 passes through the support through-hole 161 formed in the support plate 160 and is introduced into the duct hollow 420. The fluid introduced into the duct hollow 420 flows into the first vortex hollow 530 communicating therewith. In this case, it will be understood that the first vortex hollow 530 is formed inside the first vortex formation member 500a.

The fluid flows along the first vortex hollow 530. When the fluid reaches the second vortex hollow 540, a portion of the fluid continues to flow along the first vortex hollow 530 and flows into the first vortex hollow 530 of the second vortex formation member 500b. Another portion of the fluid enters the second vortex hollow 540.

At this time, a vortex protrusion 550 is formed on an inner circumferential surface of the vortex arm 520 surrounding the end of the second vortex hollow 540. Accordingly, the fluid is formed as a vortex and is discharged from the second vortex hollow 540 to the first flow space S1.

Meanwhile, the fluid (i.e., a portion of the fluid) introduced into the first vortex hollow 530 of the second vortex formation member 500b flows along the first vortex hollow 530. When the fluid reaches the second vortex hollow 540, the portion of the fluid continues to flow along the first vortex hollow 530 and flows into the third flow space S3. The portion of the fluid may be heat-exchanged with an element or the like accommodated in the third flow space S3 to cool the element or the like.

Another portion of the fluid enters the second vortex hollow 540. At this time, a vortex protrusion 550 is formed on the inner circumferential surface of the vortex arm 520 surrounding the end of the second vortex hollow 540. Accordingly, the fluid is formed as a vortex and is discharged from the second vortex hollow 540 to the second flow space S2.

Therefore, various elements disposed in the first to third flow spaces S1, S2, and S3 and a plurality of substrates 230 surrounding the first to third flow spaces S1, S2, and S3 may be effectively cooled.

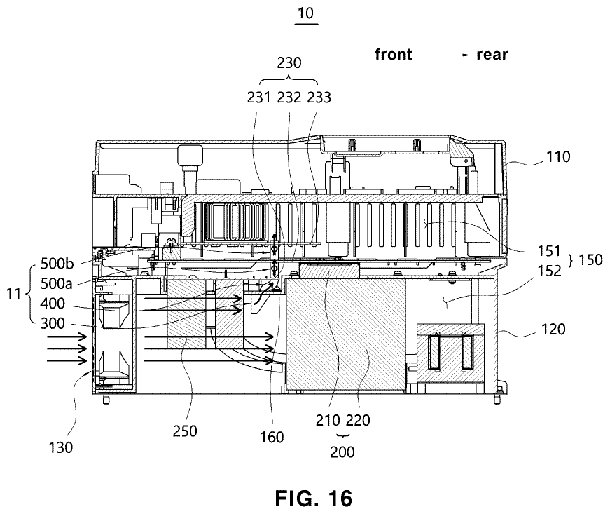

Next, referring to FIGS. 16 to 21, a fluid channel of a fluid formed inside the power device 10 according to an embodiment of the present disclosure is formed.

When the blower 130 is operated by the control signal applied to the terminal 140, external fluid is applied to the transfer force by the blower 130. The external fluid is introduced into the inside of the housing 100, specifically into the second space 152 of the second housing 120, by the applied transfer force.

A capacitor 250 is positioned between the blower 130 and the fluid channel division member 300. Therefore, the fluid introduced into the second space 152 is heat-exchanged with the capacitor 250 and proceeds to one side of the second housing 120 in the longitudinal direction, that is, the rear side in the illustrated embodiment.

At this time, the fluid channel division member 300 is positioned between the capacitor 250 and the heat dissipation member 220. Accordingly, a portion of the fluid flowing in the second space 152 is divided and introduced into the fluid channel division member 300.

The surface facing the introduced fluid, that is, the second dividing surface 312, is formed to extend obliquely upward. Therefore, the fluid entering the divided space 320 is moved upward along the second partition surface 312.

The divided space 320 communicates with the duct hollow 420 through the support through-hole 161. In addition, the duct hollow 420 communicates with the first vortex formation member 500a by the first substrate communication hole 241, and the first vortex formation member 500a communicates with the second vortex formation member 500b by the second substrate communication hole 242. Furthermore, the second vortex formation member 500b communicates with the third flow space S3 by the third substrate communication hole 243.

The fluid introduced into the duct hollow 420 via the divided space 320 may flow to the first to third flow spaces S1, S2, and S3 through the above-described process and exchange heat with the substrate 230 and the elements coupled to the substrate 230.

Therefore, even when a separate heat dissipation member for cooling the substrate 230 or the like is not provided, the substrate 230 and the elements coupled thereto may be effectively cooled.

Although exemplary embodiments of the present disclosure have been described, the idea of the present disclosure is not limited to the embodiments set forth herein. Those of ordinary skill in the art who understand the idea of the present disclosure may easily propose other embodiments through supplement, change, removal, addition, etc. of elements within the same idea, but the embodiments will be also within the scope of the present disclosure.

| | |
|---|---|
| 10: power device | 11: fluid channel module |
| 100: housing | 110: first housing |
| 111: rib | 112: air hole |
| 120: second housing | 130: blower |
| 140: terminal | 150: housing space |
| 151: first space | 152: second space |
| 160: support plate | 161: support through-hole |
| 200: electrical connection unit | 210: switching element |
| 220: heat dissipation member | 230: substrate |
| 231: first substrate | 232: second substrate |
| 233: third substrate | 240: substrate communication hole |
| 241: first substrate communication | 242: second substrate communication |
| | hole |
| 243: third substrate communication | 250: capacitor |
| hole | |
| 300: fluid channel division member | 310: dividing body |
| 311: first dividing surface | 312: second dividing surface |
| 313: third dividing surface | 314: fourth dividing surface |
| 315: coupling surface | 320: divided space |
| 330: coupling protrusion | 331: first coupling protrusion |
| 332: second coupling protrusion | 400: duct member |
| 410: duct body | 420: duct hollow |
| 430: duct corner | 500: vortex formation member |
| 500a: first vortex formation | 500b: second vortex formation |
| member | member |
| 510: vortex body | 520: vortex arm |
| 521: first arm | 522: second arm |
| 530: first vortex hollow | 540: second vortex hollow |
| 550: vortex protrusion | 560: vortex rib |
| S1: first flow space | S2: second flow space |
| S3: third flow space | |

1. A fluid channel module, comprising:
a fluid channel division member communicating with a space of a housing to allow a fluid flowing in the space to be introduced thereinto;
a duct member which is coupled to the fluid channel division member and communicates with the fluid channel division member to allow the fluid to flow therethrough; and
a vortex formation member which is coupled to the duct member and communicates with the duct member to allow the fluid to flow therethrough,
wherein the vortex formation member includes a vortex protrusion formed on an inner surface of an end in an extension direction thereof and configured such that the fluid is discharged while forming a vortex.

2. The fluid channel module of claim 1, wherein the vortex formation member comprises:
a vortex body formed to extend in one direction and having one end in the extending direction coupled to the duct member; and
a vortex arm formed to extend in the other direction, and having one end in the extending direction coupled to the vortex formation member and having the other end in the extending direction formed open to discharge the fluid.

3. The fluid channel module of claim 2, wherein the vortex formation member comprises:
a first vortex hollow formed through the inside of the vortex body along the one direction and communicating with the inside of the duct member; and
a second vortex hollow formed through the inside of the vortex arm along the other direction and communicating with the first vortex hollow and the outside, respectively.

4. The fluid channel module of claim 3, wherein the fluid is branched into one portion flowing in the first vortex hollow along the one direction; and another portion passing through the second vortex hollow from the first vortex hollow to be exposed to the outside.

5. The fluid channel module of claim 2, wherein the vortex arm are formed in plural, and the plurality of vortex arms are coupled to an outer circumference of the vortex body at different positions.

6. The fluid channel module of claim 2, wherein the vortex protrusion is formed to protrude from the inner surface of the other end of the vortex arm toward the radially inside.

7. The fluid channel module of claim 6, wherein the vortex protrusion is provided in plural, and
the plurality of vortex protrusions are disposed to be spaced apart from each other along an inner circumferential surface of the vortex arm.

8. The fluid channel module of claim 1, wherein the vortex formation member is formed to extend along one direction, and the duct member is formed to extend obliquely at a predetermined angle with respect to the one direction.

9. The fluid channel module of claim 8, wherein one end of the duct member in an extending direction is coupled to the vortex formation member, and
the other end of the duct member in the extending direction is coupled to the fluid channel division member.

10. The fluid channel module of claim 1, wherein the duct member is made of a flexible material.

11. The fluid channel module of claim 1, wherein the fluid channel division member comprises:
a dividing body coupled to the duct member; and
a divided space formed inside the dividing body and open to allow the fluid to flow therein.

12. The fluid channel module of claim 11, wherein the dividing body comprises:
a first dividing surface surrounding one portion of the divided space;
a second dividing surface extending at a predetermined angle with respect to the first dividing surface and surrounding another portion of the divided space; and
a third dividing surface and a fourth dividing surface each continuous with the first dividing surface and the second dividing surface, and disposed to face each other with the divided space interposed therebetween,
wherein the duct member extends to be inclined by the predetermined angle at which the second dividing surface extends.

13. The fluid channel module of claim 11, wherein the fluid channel division member and the duct member are disposed to face each other with a support plate, which is disposed in the space of the housing, interposed therebetween, and are coupled to one side and the other side of the support plate, respectively, and
a support through-hole formed through the inside of the support plate to communicate with the fluid channel division member and the duct member, respectively.

14. A power device comprising:
a housing in which a housing space communicating with the outside is formed;
an electrical connection unit accommodated in the housing space, and electrically connected to the outside; and
a fluid channel module coupled to the electrical connection unit, and configured to form a fluid channel of a fluid for cooling the electrical connection unit,
wherein the electrical connection unit comprises a plurality of substrates disposed to be spaced apart from each other and to be stacked,
wherein the fluid channel module comprises:
a fluid channel division member communicating with a housing space to allow a fluid flowing in the housing space to be introduced thereinto;
a duct member which is coupled to one of the plurality of the substrates and the fluid channel division member, and communicates with the fluid channel division member to allow the fluid flow therethrough; and
a vortex formation member which is coupled to the one of the substrates and another one adjacent to the one of the substrates, and communicates with the duct member to allow the fluid flow therethrough,
wherein the vortex formation member includes a vortex protrusion formed on an inner surface of an end in an extension direction thereof and configured such that the fluid is discharged while forming a vortex.

15. The power device of claim 14, wherein the vortex formation member comprises:
a first vortex formation member coupled to one pair of substrates adjacent to each other among the plurality of the substrates; and
a second vortex formation member coupled to the other pair of substrates adjacent to each other among the plurality of the substrates, and communicating with the first vortex formation member,
wherein the plurality of the substrates comprises:
a first substrate positioned at a lowermost side, wherein a lower side thereof is coupled to the duct member and an upper side thereof is coupled to the first vortex formation member;
a second substrate disposed on an upper side of the first substrate to be spaced apart from the first substrate, wherein a lower side thereof is coupled to the first vortex formation member, and an upper side thereof is coupled to the second vortex formation member; and
a third substrate disposed on an upper side of the second substrate to be spaced apart from the second substrate, wherein a lower side thereof is coupled to the second vortex formation member.

16. The power device of claim 15, wherein a first substrate through-hole, a second substrate through-hole, and a third substrate through-hole are formed through the inside of the first substrate, the second substrate, and the third substrate, respectively,
wherein the duct member communicates with the first substrate through-hole, the first vortex formation member communicates with the first substrate through-hole and the second substrate through-hole, and the second vortex formation member communicates with the second substrate through-hole.

17. The power device of claim 15, wherein the fluid introduced into the first vortex formation member is partially discharged to a first flow space, which is a space formed between the first substrate and the second substrate, and the remaining partially flows to the second vortex formation member, and
wherein the fluid introduced into the second vortex formation member is partially discharged to a second flow space, which is a space formed between the second substrate and the third substrate, and the remaining is partially discharged to a third flow space, which is a space formed on an upper side of the third substrate.

18. The power device of claim 17, wherein the vortex formation member comprises:
a vortex body extending in a direction in which the plurality of substrates are stacked, and having a first vortex hollow formed through therein along the extension direction; and
a vortex arm formed to extend in a direction different from the vortex body, and having a second vortex hollow formed through therein along the extension direction, the second vortex hollow communicating with the first vortex hollow and the flow space, respectively.

19. The power device of claim 18, wherein the vortex protrusion is located adjacent to an end of an inner surface of the vortex arm surrounding the second vortex hollow.

20. The power device of claim 14, wherein the housing comprises:
a blower coupled to one surface thereof to provide a transfer force for flowing an external fluid to the housing space, and
wherein the fluid channel division member is disposed on a fluid channel through which a fluid introduced into the housing space flows by a transfer force and allows a portion of the introduced fluid to flow into the fluid channel division member.
